(19) United States
(12) Patent Application Publication
(10) Pub. No.: US 2026/0341653 A1
(43) Pub. Date: Oct. 29, 2026

(54) PIPELINE MAINTENANCE APPARATUS FOR SEMICONDUCTOR FACILITIES

(71) Applicant: SAMSUNG ELECTRONICS CO., LTD., Suson-si (KR)

(72) Inventors: Hyungmin CHOI, Suwon-si (KE); Jaesug Jung, Suwon-si (KR); Jinje Park, Suwon-si (KR); Yunjoo Kim, Suwon-si (KR); Kimoon Lee, Suwon-si (KR); Gukpil Yang, Suwon-si (KR); Seung Hyun Seok, Suwon-si (KR); Heejae Park, Suwon-si (KR)

(73) Assignee: SAMSUNG ELECTRONICS CO., LTD., Suwon-si (KR)

(21) Appl. No.: 19/557,729

(22) Filed: Mar. 5, 2026

(30) Foreign Application Priority Data
Apr. 25, 2025 (KR) 10-2025-0054240
Aug. 11, 2025 (KR) 10-2025-0110701

(51) Int. Cl. H01J 37/32; H10P 72/00

(52) U.S. Cl. CPC H01J 37/3288; H01J 37/3244; H01J 37/32844; H01J 37/32908; H10P 72/0421; H01J 2237/022

(57) ABSTRACT

Provided is a pipeline maintenance apparatus including: a pipeline maintenance robot configured to move along an interior of a pipeline of a semiconductor facility and to remove foreign matter from the pipeline; a standby station on an outside of the pipeline, wherein the standby station is configured to provide an access passage for the pipeline maintenance robot and to provide a standby space for the pipeline maintenance robot to wait; a mobile function station configured to be selectively coupled to or separated from the standby station; a resource transfer pipe configured to move a resource used for removal of the foreign matter to the pipeline maintenance robot; and a reel configured to accommodate the resource transfer pipe and to guide a movement of the resource transfer pipe.

### CROSS-REFERENCE TO RELATED APPLICATIONS

This application is based on and claims priority to Korean Patent Application No. 10-2025-0054240, filed in the Korean Intellectual Property Office on Apr. 25, 2025, and Korean Patent Application No. 10-2025-0110701, filed in the Korean Intellectual Property Office on Aug. 11, 2025, the entire contents of which are hereby incorporated by reference.

### BACKGROUND

### 1. Field

The present disclosure relates to a pipeline maintenance apparatus for semiconductor facilities.

### 2. Description of Related Art

For stable operation and quality maintenance of semiconductor facilities, cleaning and maintenance of the interior of pipelines in semiconductor facilities is required. Due to toxic gases and the like used in processes inside the pipelines of semiconductor facilities, safety difficulties exist for workers in performing cleaning and maintenance. In addition, semiconductor facilities have a large number of pipelines and equipment densely arranged in a complex manner, so working space is often narrow and access is difficult. Due to these problems, when a uniform maintenance apparatus is introduced into various pipeline environments, work efficiency may decrease and safety problems may be caused.

### SUMMARY

Provided is a pipeline maintenance apparatus for semiconductor facilities that can be applied to various environments of semiconductor facilities and that can perform work inside pipelines.

According to an aspect of the disclosure, a pipeline maintenance apparatus includes: a pipeline maintenance robot configured to move along an interior of a pipeline of a semiconductor facility and to remove foreign matter from the pipeline; a standby station on an outside of the pipeline, wherein the standby station is configured to provide an access passage for the pipeline maintenance robot and to provide a standby space for the pipeline maintenance robot to wait; a mobile function station configured to be selectively coupled to or separated from the standby station; a resource transfer pipe configured to move a resource used for removal of the foreign matter to the pipeline maintenance robot; and a reel configured to accommodate the resource transfer pipe and to guide a movement of the resource transfer pipe.

According to an aspect of the disclosure, a pipeline maintenance apparatus includes: a pipeline maintenance robot configured to move along an interior of a pipeline of a semiconductor facility, to monitor a state of the pipeline, and to remove foreign matter from the pipeline; a standby station on an outside of the pipeline, wherein the standby station is configured to provide an access passage for the pipeline maintenance robot and to provide a standby space for the pipeline maintenance robot to wait; and a mobile function station configured to be selectively coupled to or separated from the standby station, wherein the standby station includes a first foreign matter discharge port penetrating the standby station and configured to allow the foreign matter to be discharged to an outside of the standby station, and wherein the mobile function station includes: a first foreign matter transfer pipe configured to allow the foreign matter to be discharged through the first foreign matter discharge port; a collector configured to collect the foreign matter discharged through the first foreign matter transfer pipe; and a sealer configured to inject the collected foreign matter into a foreign matter container and to seal the foreign matter container.

According to an aspect of the disclosure, a pipeline maintenance apparatus includes: a pipeline maintenance robot configured to move along an interior of a pipeline of a semiconductor facility and to remove foreign matter from the pipeline; a standby station on an outside of the pipeline, wherein the standby station is configured to provide an access passage for the pipeline maintenance robot and to provide a standby space for the pipeline maintenance robot to wait; and a mobile function station configured to be selectively coupled to or separated from the standby station, wherein the standby station includes: a foreign matter discharge port penetrating the standby station, wherein the foreign matter discharge port is configured to allow the foreign matter to be discharged to an outside of the standby station; and a resource connector penetrating the standby station, wherein the resource connector is configured to allow a resource used for removal of the foreign matter by the pipeline maintenance robot to be supplied from an outside of the standby station, and wherein the mobile function station includes: a foreign matter transfer pipe configured to be selectively coupled to or separated from the foreign matter discharge port, wherein the foreign matter transfer pipe is configured to move the foreign matter discharged through the foreign matter discharge port; a collector configured to collect the foreign matter discharged through the foreign matter transfer pipe; a foreign matter pump configured to apply a negative pressure in the foreign matter transfer pipe to move the foreign matter from the foreign matter discharge port to the collector; a resource transfer pipe configured to allow the resource to move to the pipeline maintenance robot; and a reel configured to accommodate the resource transfer pipe and to guide a movement of the resource transfer pipe.

According to one or more embodiments of the present disclosure, a pipeline maintenance apparatus for semiconductor facilities that flexibly responds to environmental constraints and different requirements of various industrial sites can be provided by modularizing a standby station with a mobile function station that can be separated therefrom.

The present disclosure is not limited to the above-described aspects and features, and additional aspects and features that are not mentioned may be clearly understood by those skilled in the art from the description below.

### BRIEF DESCRIPTION OF DRAWINGS

The above and other aspects and features of certain embodiments of the present disclosure will be more apparent from the following description taken in conjunction with the accompanying drawings, in which:

FIG. 1 illustrates an example of a pipeline maintenance apparatus for semiconductor facilities according to one or more embodiments of the present disclosure;

FIG. 2 illustrates an example of a pipeline maintenance apparatus for semiconductor facilities according to one or more embodiments of the present disclosure;

FIG. 3 illustrates an example of a pipeline maintenance apparatus for semiconductor facilities according to one or more embodiments of the present disclosure;

FIG. 4 illustrates an example of a pipeline maintenance apparatus for semiconductor facilities according to one or more embodiments of the present disclosure;

FIG. 5 illustrates an example of a pipeline maintenance apparatus for semiconductor facilities according to one or more embodiments of the present disclosure;

FIGS. 6 to 8 are diagrams for explaining a sealer according to one or more embodiments of the present disclosure;

FIG. 9 illustrates an example of a pipeline maintenance apparatus for semiconductor facilities according to one or more embodiments of the present disclosure;

FIG. 10 illustrates an example of a pipeline maintenance apparatus for semiconductor facilities according to one or more embodiments of the present disclosure;

FIG. 11 illustrates an example of a resource transfer pipe located at an entry portion of a storage device according to one or more embodiments of the present disclosure;

FIGS. 12 and 13 are diagrams for explaining an example of a guide according to one or more embodiments of the present disclosure;

FIG. 14 is a diagram illustrating an example of a pipeline maintenance apparatus for semiconductor facilities according to one or more embodiments of the present disclosure;

FIGS. 15 to 17 are diagrams for explaining an example of an opening and closing device according to one or more embodiments of the present disclosure;

FIG. 18 illustrates an example of a pipeline maintenance apparatus for semiconductor facilities according to one or more embodiments of the present disclosure; and

FIG. 19 is a diagram for explaining an example of a robot according to one or more embodiments of the present disclosure.

### DETAILED DESCRIPTION

Hereinafter, a pipeline maintenance apparatus, system, and method for semiconductor facilities according to one or more embodiments of the present disclosure will be described in detail with reference to the drawings.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

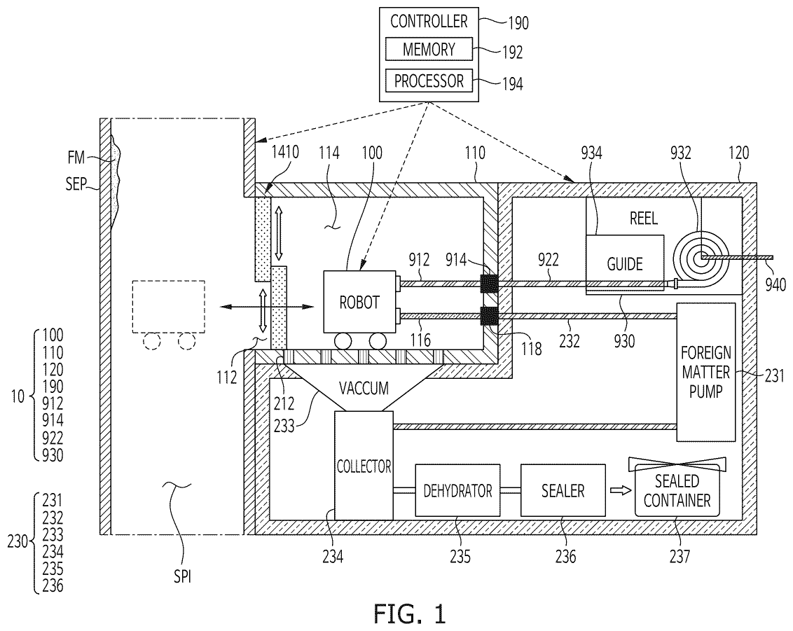

FIG. 1 is a diagram for explaining an example of a pipeline maintenance apparatus 10 for semiconductor facilities according to one or more embodiments of the present disclosure. The pipeline maintenance apparatus 10 for semiconductor facilities (hereinafter referred to as “pipeline maintenance apparatus 10”) may include a pipeline maintenance robot 100 (hereinafter referred to as “robot 100”), a standby station 110, and a mobile function station 120 (hereinafter referred to as “function station 120”). In addition, the pipeline maintenance apparatus 10 may further include a resource connector 914, resource transfer pipes 912 and 922, a reel 930, an opener/closer 1410, and a controller 190.

A fluid used in a semiconductor manufacturing process may move in a pipeline SEP of a semiconductor facility. An internal space SPI may be formed in the pipeline SEP, and the fluid may move through the internal space SPI. An inner wall of the pipeline SEP may be coated, surface-treated, or the like so that contamination of the internal space SPI of the pipeline is minimized.

Foreign matter (e.g., debris) FM may be disposed in the internal space SPI of the pipeline. For example, as a fluid flows along the pipeline SEP, the fluid may accumulate in some areas without moving, thereby forming the foreign matter FM.

In one or more embodiments, the pipeline SEP may include various sensors configured to acquire information related to the pipeline SEP for maintenance of the pipeline SEP. For example, the pipeline SEP may include a pressure sensing sensor that monitors pressure inside the pipeline, a sensor that monitors the presence, type, volume, etc. of the foreign matter FM inside the pipeline SEP, a sensor that monitors a flow rate inside the pipeline SEP, and the like. The controller 190 may acquire information generated by the sensors included in the pipeline SEP.

The robot 100 may move along the interior of the pipeline SEP of the semiconductor facility and may remove the foreign matter FM in the pipeline SEP. The robot 100 may perform cleaning, inspection, and/or maintenance work of the pipeline SEP. For example, the movement mechanism of the robot 100 may include a plurality of traveling wheels that can be expanded toward the inner surface of the pipeline SEP or compressed in the opposite direction through the control of pneumatic pressure supplied to a cylinder. However, the disclosure is not limited thereto, and the movement mechanism of the robot 100 may be performed in various ways. In addition, the robot 100 may include various tools (e.g., a cleaning tool, a suction tool, etc.) to remove the foreign matter FM in the pipeline SEP. The robot 100 may further include various monitoring sensors (e.g., a monitoring sensor for monitoring the interior of the pipeline SEP) to monitor the interior of the pipeline SEP.

In one or more embodiments, the robot 100 may move along the internal space SPI of the pipeline. For example, when the pipeline SEP is in an active state in which a fluid flows, the robot 100 may move along the internal space SPI of the pipeline. In addition, even when the pipeline SEP is in an idle state in which a fluid does not move, the robot 100 may move along the internal space SPI of the pipeline.

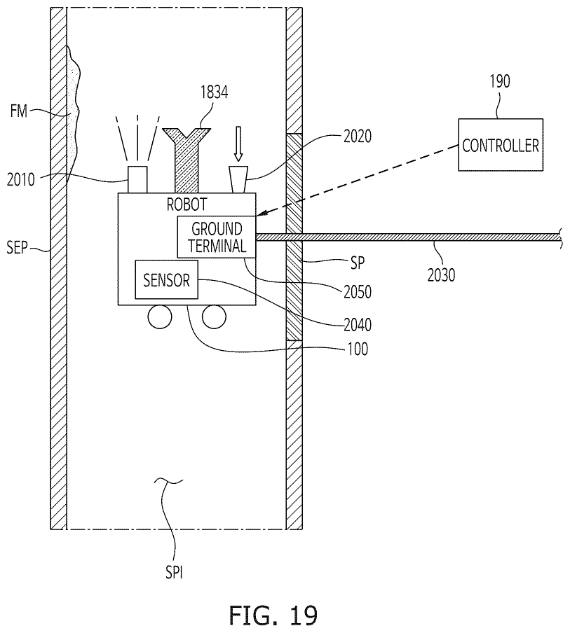

In one or more embodiments, the robot 100 may include a material having chemical resistance to a fluid flowing in the internal space SPI of the pipeline. For example, a body and/or an outer surface of the robot 100 may include a nickel alloy and/or stainless steel. In this case, the robot 100 may have corrosion resistance to an etching gas containing fluorine gas (F2), chlorine gas (Cl2), or the like. As another example, the robot 100 may include a fluororesin-coated material such as polytetrafluoroethylene (PTFE) or fluorinated ethylene propylene (FEP). In this case, the robot 100 may have chemical resistance to a gas used in a plasma process containing ammonia gas (NH3) or the like. As another example, the robot 100 may include a moving device (e.g., a wheel) containing ethylene tetrafluoroethylene (ETFE), wear-resistant rubber, or the like. In this case, the robot 100 may have chemical resistance to hydrofluoric acid (HF) or the like. As another example, the robot 100 may include an electronic component protected by an aluminum anodizing treatment or a PTFE coating treatment sealed case. In this case, the robot 100 including the electronic component may have chemical resistance to an acidic gas environment (e.g., sulfuric acid (H2SO4) gas, hydrochloric acid (HCl) gas, etc.). As another example, the robot 100 may include a sensor coated with sapphire glass. Such a sensor may sense a temperature, acidity (pH), etc. of a fluid in a state of having chemical resistance to the fluid flowing inside the pipeline SEP. The robot 100 including such a sensor may have chemical resistance to a gas used for plasma etching (e.g., sulfur hexafluoride (SF6), nitric acid (HNO3), sulfuric acid (H2SO4) gas, etc.). Accordingly, the robot 100 may communicate with the controller 190 without being damaged inside the pipeline SEP in the active state and may perform various operations and/or tasks. A specific structure of the robot 100 will be described in detail with reference to FIG. 19. In one or more embodiments, the robot 100 may include a material having chemical resistance to a fluid flowing in the internal space SPI of the pipeline. For example, a body and/or an outer surface of the robot 100 may include a nickel alloy and/or stainless steel. In this case, the robot 100 may exhibit corrosion resistance to an etching gas containing fluorine gas (F2), chlorine gas (Cl2), or the like. As another example, the robot 100 may include a fluororesin-coated material such as polytetrafluoroethylene (PTFE) or fluorinated ethylene propylene (FEP). In this case, the robot 100 may exhibit chemical resistance to a gas used in a plasma process containing ammonia gas (NH3) or the like. As yet another example, the robot 100 may include a moving device (e.g., wheels) including ethylene tetrafluoroethylene (ETFE), wear-resistant rubber, or the like. In this case, the robot 100 may exhibit chemical resistance to hydrofluoric acid (HF) or the like. As still another example, the robot 100 may include electronic components protected by a sealed case subjected to aluminum anodizing treatment or PTFE coating treatment. In this case, the robot 100 including the electronic components may exhibit chemical resistance to an acidic gas environment (e.g., sulfuric acid (H2SO4) gas, hydrochloric acid (HCl) gas, etc.). As a further example, the robot 100 may include a sensor coated with sapphire glass. Such a sensor, while possessing chemical resistance to the fluid flowing inside the pipeline SEP, may sense the temperature, pH, etc., of the fluid. The robot 100 including such a sensor may exhibit chemical resistance to gases used for plasma etching (e.g., sulfur hexafluoride (SF6), nitric acid (HNO3), sulfuric acid (H2SO4) gas, etc.). Accordingly, the robot 100 can communicate with the controller 190 and perform various operations and/or tasks without being damaged inside the pipeline SEP while the pipeline is in an operating state. A specific structure of the robot 100 will be described in detail with reference to FIG. 19.

In one or more embodiments, the standby station 110 may be provided on the outside of the pipeline SEP. For example, an opening penetrating the pipeline SEP may be formed in the pipeline SEP, and the standby station 110 may be disposed on an outer surface of the pipeline SEP to cover the opening. The opening formed in the pipeline SEP may communicate with the internal space SPI of the pipeline. The robot 100 may move between a standby space 114 and the internal space SPI of the pipeline through the opening.

The standby station 110 may provide the standby space 114 for the robot 100 to wait. For example, the standby space 114 may be formed inside the standby station 110, and one side of the standby station 110 may be opened. The opened one side of the standby station 110 may be connected to the internal space SPI of the pipeline to provide an access passage 112 for the robot 100. The access passage 112 may communicate the internal space SPI of the pipeline with the standby space 114.

In one or more embodiments, an idle robot 100 may wait in the standby space 114. For example, the robot 100 may be located in the standby space 114 until a work command is received from the controller 190. In addition, the standby space 114 may be used as a space for maintenance work of the robot 100 (e.g., cleaning of the robot 100, inspection, tool replacement, etc.).

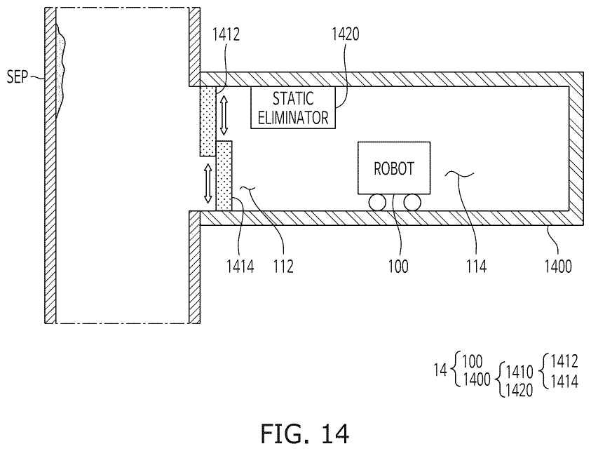

In one or more embodiments, the standby station 110 may include an opener/closer 1410 that opens or closes the access passage 112 of the pipeline maintenance robot 100. The opener/closer 1410 may selectively communicate or block between the standby space 114 and the interior of the pipeline SEP. For example, the opener/closer 1410 may include a first opening and closing door and a second opening and closing door that move while facing each other. A specific structure and function of the opener/closer 1410 will be described in detail with reference to FIG. 14.

In one or more embodiments, the standby station 110 may have various sizes. For example, the size of the standby station 110 may be determined based on a surrounding installation environment of the pipeline SEP, the size and operating range of the robot 100, the size of a device disposed inside the standby station 110 (e.g., the opener/closer 1410, a tool replacer, a cleaner, etc.), and the like.

The function station 120 may be selectively coupled to or separated from the standby station 110. For example, the function station 120 may be docked to an outer wall of the standby station 110 to be coupled to the standby station 110, and may be undocked from the outer wall of the standby station 110 to be separated from the standby station 110. As another example, the function station 120 may be disposed to be spaced apart from the standby station 110 and may be connected to the standby station 110 through a pipeline member (e.g., a foreign matter discharge pipe, a resource transfer pipe, a hose, a cable, etc.). The pipeline member may be releasably coupled to a docking port formed in the function station 120 and/or the standby station 110. Accordingly, the function station 120 may be selectively coupled to or separated from the standby station 110.

In one or more embodiments, the function station 120 may include a moving device to be coupled to or separated from the standby station 110. For example, a plurality of wheels may be mounted on a lower portion of the function station 120. The function station 120 may be disposed at a position adjacent to the standby station 110 through the plurality of wheels and may be coupled to the standby station 110. In addition, the function station 120 may be separated from the standby station 110 and disposed and stored in a separate space.

In one or more embodiments, the function station 120 may have various sizes. For example, the size of the function station 120 may be determined based on a surrounding installation environment of the pipeline SEP and the standby station 110, the size and operating range of the robot 100, the size of a function unit mounted inside the function station 120 (e.g., the reel 930, a foreign matter processor 230, etc.), and the like.

Referring to FIG. 1, the function station 120 may include a housing that partitions an internal space. However, the function station 120 is not limited thereto. For example, the function station 120 may include a structure such as an open frame or a cart on which a function unit (e.g., the foreign matter processor 230, etc.) is mounted without forming a physically partitioned space. As another example, the function station 120 may refer to at least one function unit itself without a separate structure.

The function station 120 may include the foreign matter processor 230 configured to process the foreign matter FM removed by the robot 100. For example, the robot 100 may remove the foreign matter FM inside the pipeline SEP and may move the foreign matter to the foreign matter processor 230. The foreign matter processor 230 may perform a predetermined process (e.g., dehydration, collection, suction, etc.) on the foreign matter. The foreign matter processor 230 may seal and store the foreign matter FM or may discharge the foreign matter FM.

In one or more embodiments, the standby station 110 may include a first foreign matter discharge port 118 formed penetrating the standby station 110 such that the foreign matter is discharged to the outside of the standby station 110. For example, the first foreign matter discharge port 118 may be connected to a foreign matter discharge pipe 116, and the first foreign matter discharge port 118 and the interior of the foreign matter discharge pipe 116 may communicate with each other. The foreign matter moving along the foreign matter discharge pipe 116 may be discharged to the outside of the standby station 110 through the first foreign matter discharge port 118.

In one or more embodiments, one end of the foreign matter discharge pipe 116 may be connected to the first foreign matter discharge port 118, and the other end of the foreign matter discharge pipe 116 may be docked with the robot 100. For example, the robot 100 may include a docking port. The other end of the foreign matter discharge pipe 116 may be docked to or undocked from the docking port of the robot 100. In another embodiment, one end of the foreign matter discharge pipe 116 may be connected to the robot 100, and the other end of the foreign matter discharge pipe 116 may be docked with the first foreign matter discharge port 118. For example, a docking port may be formed on an inner surface of the first foreign matter discharge port 118. The other end of the foreign matter discharge pipe 116 may be docked to or undocked from the docking port of the first foreign matter discharge port 118.

In one or more embodiments, the standby station 110 may include a docking device configured to control docking of the foreign matter discharge pipe 116. For example, the docking device may include a gripper for gripping the foreign matter discharge pipe 116, a driving unit connected to the gripper (e.g., a multi-joint robot arm), and the like. The gripper may grip the foreign matter discharge pipe 116, and the driving unit may move the gripper gripping the foreign matter discharge pipe 116 to a designated position. For example, the driving unit may align the other end of the foreign matter discharge pipe 116 with the docking port of the robot 100 or the docking port of the first foreign matter discharge port 118. As another example, the driving unit may separate the other end of the foreign matter discharge pipe 116 from the docking port of the robot 100 or the docking port of the first foreign matter discharge port 118 and move the other end to a standby position.

In one or more embodiments, the foreign matter processor 230 may process the foreign matter discharged to the outside of the standby station 110. For example, the foreign matter processor 230 may include a foreign matter pump 231, a first foreign matter transfer pipe 232, a vacuum 233, a collector 234, a dehydrator 235, and a sealer 236. The foreign matter discharged from the first foreign matter discharge port 118 may move in the first foreign matter transfer pipe 232. The collector 234 may collect the foreign matter moved through the first foreign matter transfer pipe 232. The foreign matter pump 231 may apply a negative pressure in the first foreign matter transfer pipe 232 to induce movement of the foreign matter to the collector 234. The dehydrator 235 may dehydrate the foreign matter collected by the collector 234. The sealer 236 may inject the collected foreign matter into a foreign matter container and may seal the foreign matter container. The sealer 236 may form a sealed container 237 by injecting the foreign matter into the foreign matter container and sealing the foreign matter container.

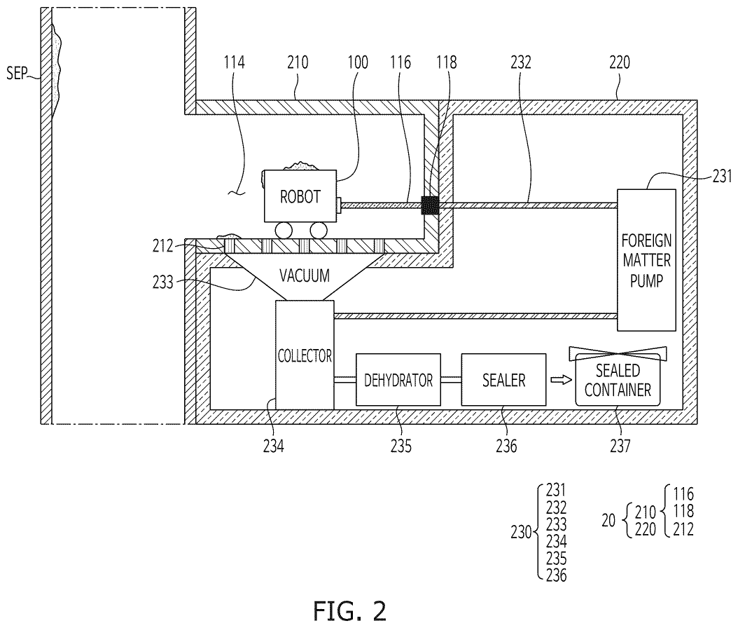

In one or more embodiments, a standby station 210 may include a second foreign matter discharge port 212 formed penetrating the standby station 210. The vacuum 233 of a function station 220 may suck the foreign matter in the standby space 114 through the second foreign matter discharge port 212. The collector 234 may further collect the foreign matter sucked by the vacuum 233. A specific structure and function of the foreign matter processor 230 will be described in detail with reference to FIG. 2.

In one or more embodiments, a resource connector 914 may be formed penetrating the standby station 110 such that a resource is supplied from the outside of the standby station 110. A first resource transfer pipe 912 may provide the resource supplied through the resource connector 914 to the robot 100. A function station 120 may include a second resource transfer pipe 922 that supplies the resource into the standby station 110 through the resource connector 914. The second resource transfer pipe 922 may be connected to a third resource transfer pipe 940 connected to a resource supply device. The resource may be supplied to the robot 100 along the third resource transfer pipe 940, the second resource transfer pipe 922, and the first resource transfer pipe 912.

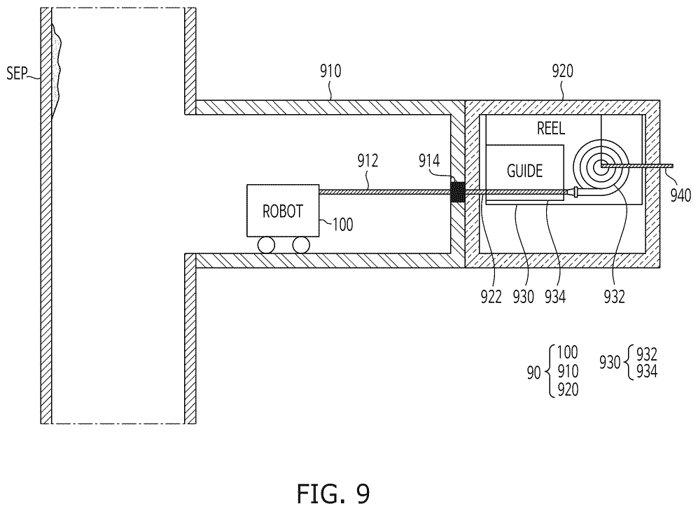

In one or more embodiments, the function station 120 may include a reel 930 that accommodates the second resource transfer pipe 922 and guides the movement of the second resource transfer pipe 922. The reel 930 may include a storage device 932 configured to accommodate the second resource transfer pipe 922 and a guide 934 disposed at a discharge portion of the storage device 932 and configured to guide the transfer of the second resource transfer pipe 922. A specific structure and function of the reel 930 will be described in detail with reference to FIGS. 9 and 11 through 13.

In one or more embodiments, the controller 190 may comprehensively manage and control each component of the pipeline maintenance apparatus 10. For example, the controller 190 may control the robot 100, the standby station 110, the function station 120, the foreign matter processor 230, the reel 930, and/or the opener/closer 1410. In an example, the controller 190 may command a cleaning operation of the robot 100. In another example, the controller 190 may command the standby station 110 to replace a cleaning tool of the robot 100. As another example, the controller 190 may command the function station 120 so that the foreign matter processor 230 of the function station 120 collects the foreign matter discharged from the standby station 110. Referring to FIG. 1, the controller 190 is illustrated as being disposed outside the pipeline SEP, the standby station 110, and/or the function station 120, but may be implemented in the pipeline SEP, the standby station 110, and/or the function station 120.

In one or more embodiments, a single function station 120 may include a plurality of function units (e.g., the foreign matter processor 230, the opener/closer 1410, the reel 930, an air circulation device, a tool replacer, a cleaner, etc.). However, the disclosure is not limited thereto. For example, each of at least one function station 120 may include at least one function unit, and each function station 120 may be coupled to or separated from a single standby station 110.

In one or more embodiments, the pipeline maintenance apparatus 10 may be disposed in various spaces of a semiconductor manufacturing facility. For example, the semiconductor manufacturing facility may include spaces ranging from the uppermost level of the facility structure (e.g., a rooftop mechanical room) to the lowermost level of the facility structure (e.g., a sub-fab). The pipeline maintenance apparatus 10 may be disposed in spaces extending from the uppermost level to the lowermost level of the semiconductor manufacturing facility structure.

In one or more embodiments, the robot 100 and/or the controller 190 may include a memory (e.g., memory 192) and a processor (e.g., processor 194). The memory may include any non-transitory computer-readable recording medium. According to one or more embodiments, the memory may include a permanent mass storage device such as random access memory (RAM), read only memory (ROM), a disk drive, a solid state drive (SSD), or a flash memory. As another example, a permanent mass storage device such as a ROM, an SSD, a flash memory, or a disk drive may be included in the controller 190 as a separate permanent storage device distinct from the memory. In addition, an operating system and at least one program code may be stored in the memory.

The processor may be configured to process instructions of a computer program stored in the memory by performing basic arithmetic, logic, and input/output operations. The instructions may be provided by the memory or a communication module to an external device (e.g., the robot 100, the pipeline SEP, the standby station 110, the function station 120, etc.) or to another external system.

Additionally, the robot 100 and/or the controller 190 may further include a communication module. The communication module may provide a configuration or function enabling the robot 100 and the controller 190 to communicate with each other and may provide a configuration or function enabling the controller 190 to communicate with an external device (e.g., the robot 100, the pipeline SEP, the standby station 110, the function station 120, etc.) or another external system. For example, a control signal, command, data, etc. provided under control of the processor of the controller 190 may be transmitted through the communication module to the external device and/or the external system via a communication module of the external device and/or the external system.

As described above, the pipeline maintenance apparatus 10 may flexibly respond to requirements of an industrial site. For example, a bulky or low-frequency-use configuration such as the foreign matter processor 230 may be included in the function station 120 to be separated. Accordingly, the pipeline maintenance apparatus 10 may be used even in a space with a small installation space and may be used in various pipeline environments. In addition, the robot 100 may perform dangerous pipeline internal inspection and/or cleaning work, thereby reducing a risk of workers being exposed to harmful gases or toxic substances. Accordingly, stability of a working environment may be improved.

FIG. 2 is a diagram for explaining an example of a pipeline maintenance apparatus 20 for semiconductor facilities according to one or more embodiments of the present disclosure. The pipeline maintenance apparatus 20 may include a robot 100, a standby station 210, and a function station 220. Unlike the pipeline maintenance apparatus 10 of FIG. 1, the pipeline maintenance apparatus 20 may not include a resource transfer pipe, a resource connector, a reel, and an opener/closer. Hereinafter, in the description of FIG. 2, contents overlapping with those of FIG. 1 may be omitted or briefly described.

The standby station 210 may be provided on the outside of a pipeline SEP to provide an access passage for the robot 100 and may provide a standby space 114 for the robot 100 to wait. In one or more embodiments, the standby station 210 may include a foreign matter discharge pipe 116, a first foreign matter discharge port 118, and a second foreign matter discharge port 212.

In one or more embodiments, the robot 100 may be supplied with a resource used to remove foreign matter in various ways. For example, the robot 100 may be driven using a built-in resource. In an example, the robot 100 may include a power supply device (e.g., a battery, etc.) for driving, a fluid storage device (e.g., an air tank, a water tank, etc.) for removing the foreign matter, a communication module for communicating with a controller (e.g., the controller 190 of FIG. 1), etc., thereby being supplied with the resource. As another example, the robot 100 may be supplied with the resource from the outside of the standby station 210 without passing through the function station 220. For example, a pipeline member connected to an external resource supply source may penetrate the standby station 210 and may be connected to the robot 100. The resource supplied from the resource supply source may be provided to the robot 100 along the pipeline member.

The function station 220 may be selectively coupled to or separated from the standby station 210. In one or more embodiments, the function station 220 may include a foreign matter processor 230 for processing foreign matter, and the foreign matter processor 230 may include a plurality of function units. For example, the foreign matter processor 230 may include a foreign matter pump 231, a first foreign matter transfer pipe 232, a vacuum 233, a collector 234, a dehydrator 235, and a sealer 236.

In one or more embodiments, the first foreign matter transfer pipe 232 may connect the interior of the standby station 210 and the collector 234. The first foreign matter transfer pipe 232 may provide a movement path of the foreign matter directed from the interior of the standby station 210 toward the collector 234. For example, the first foreign matter transfer pipe 232 may be connected to the first foreign matter discharge port 118 of the standby station 210 and may guide the foreign matter discharged from the first foreign matter discharge port 118 to the collector 234.

In one or more embodiments, the foreign matter pump 231 may apply a negative pressure in the first foreign matter transfer pipe 232. Movement of the foreign matter to the collector 234 may be induced by the applied negative pressure. For example, the robot 100 (e.g., a foreign matter storage space of the robot 100, a suction tool of the robot 100, a foreign matter discharge unit of the robot 100, etc.), the foreign matter discharge pipe 116, the first foreign matter discharge port 118, and the first foreign matter transfer pipe 232 may communicate with each other to form a foreign matter path. The foreign matter pump 231 may form a negative pressure in the foreign matter path, and the foreign matter disposed on the foreign matter path may be transferred to the collector 234 via the robot 100, the foreign matter discharge pipe 116, the first foreign matter discharge port 118, and the first foreign matter transfer pipe 232.

In one or more embodiments, the standby station 210 may include a second foreign matter discharge port 212 formed through the standby station 210. For example, the second foreign matter discharge port 212 may be formed on the bottom of the standby station 210 so that foreign matter disposed in the standby space 114 can be discharged toward the second foreign matter discharge port 212. However, the present disclosure is not limited thereto, and the second foreign matter discharge port 212 may be formed in various portions of the standby station 210.

In one or more embodiments, the vacuum 233 may suck the foreign matter in the standby space 114 through the second foreign matter discharge port 212. For example, a suction portion of the vacuum 233 may communicate with the second foreign matter discharge port 212. The vacuum 233 may apply a negative pressure to the second foreign matter discharge port 212 to suck the foreign matter in the standby space 114 through the second foreign matter discharge port 212.

In one or more embodiments, the vacuum 233 may transfer the foreign matter sucked through the second foreign matter discharge port 212 to the collector 234. In addition, the first foreign matter transfer pipe 232 may transfer the foreign matter discharged through the first foreign matter discharge port 118 to the collector 234. That is, the collector 234 may collectively collect the foreign matter discharged through the first foreign matter discharge port 118 and the foreign matter discharged through the second foreign matter discharge port 212. Thereafter, the collector 234 may transfer the collected foreign matter to the dehydrator 235.

In one or more embodiments, the collector 234 may include a space for accommodating the collected foreign matter. For example, the collector 234 may include a storage container such as a plastic bag or a drum. The foreign matter accommodated in the collector 234 may be temporarily stored in the collector 234 and then discharged together with the storage container. As another example, the collector 234 may be connected to another device (e.g., the dehydrator 235, the sealer 236, an external device of the function station 220, etc.) and may transfer the collected foreign matter to the corresponding device. In one or more embodiments, the dehydrator 235 may dehydrate the foreign matter collected by the collector 234. The dehydrator 235 may be disposed at a rear end of the collector 234 and may receive the collected foreign matter from the collector 234. The dehydrator 235 may be implemented in various ways. For example, the dehydrator 235 may include a centrifuge that separates a liquid component through centrifugal force, a screw press in which a screw rotates and compresses the foreign matter, a filter press that filters the foreign matter by passing the foreign matter between a plurality of filters, etc. In an example, the dehydrator 235 may separate a liquid component and a solid component separated through a dehydration process of the foreign matter and transfer the liquid component and the solid component to the sealer 236. In another example, the dehydrator 235 may separately process the separated liquid component (or the separated solid component) and may transfer the separated solid component (or the separated liquid component) to the sealer 236.

As another example, the dehydrator 235 may include a heating member for heating the foreign matter, a ventilation member for discharging vaporized vapor, and the like. The dehydrator 235 may vaporize moisture contained in the foreign matter to increase a dryness level of the foreign matter. Accordingly, the dehydrator 235 may reduce a volume and weight of the collected foreign matter, thereby facilitating storage and transportation of the foreign matter.

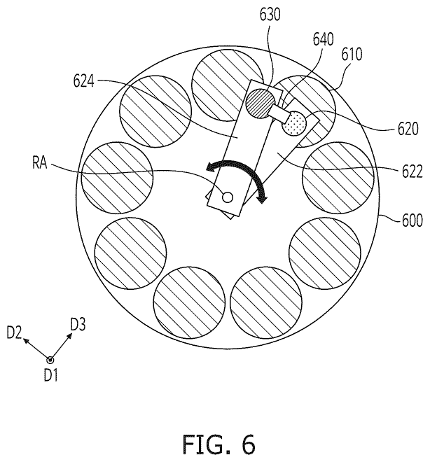

In one or more embodiments, the sealer 236 may seal the foreign matter collected by the collector 234. Referring to FIG. 2, the sealer 236 may be disposed at a rear end of the dehydrator 235 and may receive the foreign matter dehydrated by the dehydrator 235. However, the disclosure is not limited thereto, and the sealer 236 may be disposed at the rear end of the collector 234 and may receive the collected foreign matter from the collector 234 without passing through the dehydrator 235. The sealer 236 may include a foreign matter container and a sealing cap used to seal the collected foreign matter. A process of sealing the foreign matter by the sealer 236 and a specific structure of the foreign matter container and the sealing cap will be described in detail with reference to FIGS. 6 to 8.

In one or more embodiments, the sealer 236 may form a sealed container 237 by injecting and sealing the foreign matter into the foreign matter container. The sealer 236 may dispose the sealed container 237 in a separate space inside the function station 220. For example, after the function station 220 is separated from the standby station 210, a worker may discharge the sealed container 237. As another example, the function station 220 may include a discharge device, and the discharge device may discharge the sealed container 237 to the outside of the function station 220.

As described above, through a series arrangement of each function unit (e.g., the foreign matter pump 231, the vacuum 233, the collector 234, the dehydrator 235, the sealer 236, etc.), the function station 220 may automate a process including collection, processing, and sealing of the foreign matter to stably and efficiently process the foreign matter.

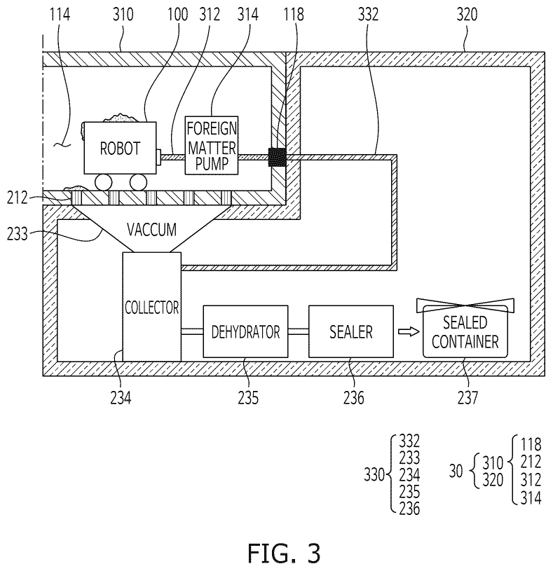

FIG. 3 is a diagram for explaining an example of a pipeline maintenance apparatus 30 for semiconductor facilities according to one or more embodiments of the present disclosure.

The pipeline maintenance apparatus 30 may include a robot 100, a standby station 310, and a function station 320. In one or more embodiments, the standby station 310 may include a foreign matter discharge pipe 312, a first foreign matter discharge port 118, a second foreign matter discharge port 212, and a foreign matter pump 314. Further, the function station 320 may include a foreign matter processor 330 for processing foreign matter, and the foreign matter processor 330 may include a plurality of functional units. For example, the foreign matter processor 330 may include a foreign matter transfer pipe 332, a vacuum 233, a collector 234, a dehydrator 235, and a sealer 236. The standby station 310 of FIG. 3 may further include the foreign matter pump 314 in addition to the configuration of the standby station 210 of FIG. 2. The foreign matter processor 330 may include the configuration of the foreign matter processor 230 of FIG. 2 excluding the foreign matter pump 231. Hereinafter, in the description of FIG. 3, details overlapping with those of FIGS. 1 and 2 will be omitted or briefly described.

In one or more embodiments, the foreign matter discharge pipe 312 may be connected to the first foreign matter discharge port 118 and may be selectively coupled to or separated from the robot 100. For example, one end of the foreign matter discharge pipe 312 may be connected to the first foreign matter discharge port 118, and the other end of the foreign matter discharge pipe 312 may be connected to the robot 100 (e.g., a docking port of the robot). The foreign matter discharge pipe 312 may guide the foreign matter removed by the robot 100 toward the first foreign matter discharge port 118.

In one or more embodiments, the foreign matter pump 314 may apply a positive pressure (e.g., a positive pressure formed by injecting compressed air) in the foreign matter discharge pipe 312. Movement of the foreign matter to the collector 234 may be induced by the applied positive pressure. For example, the robot 100 (e.g., a foreign matter storage space of the robot 100, a suction tool of the robot 100, a foreign matter discharge unit of the robot 100, etc.), the foreign matter discharge pipe 312, the first foreign matter discharge port 118, and the foreign matter transfer pipe 332 may communicate with each other to form a foreign matter path. The foreign matter pump 314 may form a positive pressure in the foreign matter path, and the foreign matter disposed on the foreign matter path may be transferred to the collector 234 via the robot 100, the foreign matter discharge pipe 312, the first foreign matter discharge port 118, and the foreign matter transfer pipe 332. Thereafter, the foreign matter collected by the collector 234 may be subjected to subsequent processing (e.g., dehydration, sealing, etc.).

When there is a space allowance relative to the standby station 310, the standby station 310 may be provided with the foreign matter pump 314. The foreign matter pump 314 using a positive pressure may be useful when moving relatively heavy foreign matter. The foreign matter pump 314 may be provided in the standby station 310 in consideration of characteristics of a pipeline, a state of the foreign matter, etc., or the foreign matter pump 231 may be provided in the function station 220 as in the embodiment of FIG. 2.

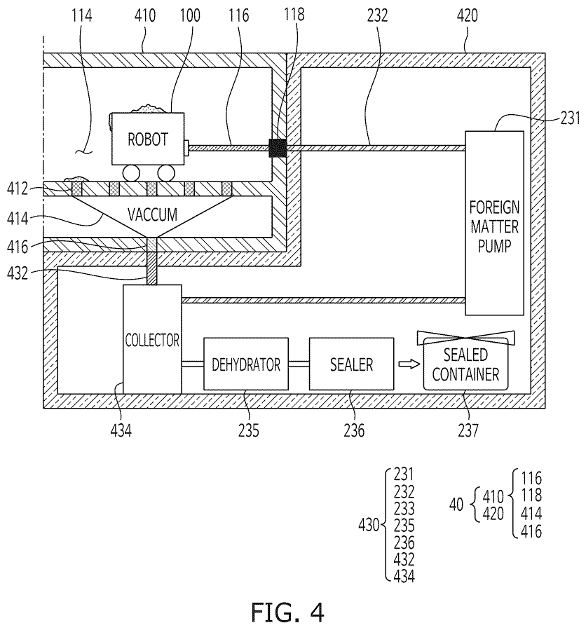

FIG. 4 is a diagram for explaining an example of a pipeline maintenance apparatus 40 for semiconductor facilities according to one or more embodiments of the present disclosure.

The pipeline maintenance apparatus 40 may include a robot 100, a standby station 410, and a function station 420. In one or more embodiments, the standby station 410 may include a foreign matter discharge pipe 116, a first foreign matter discharge port 118, and a vacuum 414. In addition, the function station 420 may include a foreign matter processor 430 for processing foreign matter, and the foreign matter processor 430 may include a plurality of function units. For example, the foreign matter processor 430 may include the foreign matter pump 231, the first foreign matter transfer pipe 232, a collector 434, the dehydrator 235, the sealer 236, and a second foreign matter transfer pipe 432. The standby station 410 of FIG. 4 may further include a suction port 412, the vacuum 414, and a second foreign matter discharge port 416 in the standby station 210 of FIG. 2. The foreign matter processor 430 of FIG. 4 may further include the second foreign matter transfer pipe 432 in which the foreign matter sucked from the vacuum 414 of the standby station 410 moves, unlike the foreign matter processor 230 of FIG. 2 including the vacuum. Hereinafter, in the description of FIG. 4, contents overlapping with those of FIGS. 1 to 3 will be omitted or briefly described.

Referring to FIG. 4, the standby station 410 may have a double bottom structure. For example, the standby station 410 may include an upper bottom on which the robot 100 moves and a lower bottom disposed to be spaced apart from a lower portion of the upper bottom. A device space may be formed between the upper bottom and the lower bottom. The vacuum 414 may be located in the device space. A suction port 412 may be formed in the upper bottom, and the foreign matter in a standby space 114 may be introduced into the vacuum 414 of the device space through the suction port 412. However, a structure of the standby station 410 is not limited thereto. For example, the structure of the standby station 410 may be variously determined based on a type and size of a device disposed inside the standby station 410, a size and operating range of the robot 100, and the like.

In one or more embodiments, the vacuum 414 may suck the foreign matter in the standby space 114. Referring to FIG. 4, the vacuum 414 may be disposed in a separate space separated from the standby space 114. The suction port 412 may communicate with the standby space 114 and the vacuum 414. For example, the suction port 412 may be in a slit form along a periphery of the standby space 114, a grid form in which a plurality of holes are perforated, or the like. The vacuum 414 may apply a negative pressure to the suction port 412 to suck the foreign matter in the standby space 114. However, the disclosure is not limited thereto, and the vacuum 414 may be disposed in the standby space 114 and may suck the foreign matter in the standby space 114 without using the suction port 412.

In one or more embodiments, the standby station 410 may include a second foreign matter discharge port 416 formed through the standby station 410. For example, the second foreign matter discharge port 416 may be disposed at a rear end of the vacuum 414 and connected to the vacuum 414. For example, the second foreign matter discharge port 416 may be formed on the bottom of the standby station 410 so that foreign matter sucked by the vacuum 414 can be discharged to the outside of the standby station 410 through the second foreign matter discharge port 416. However, the present disclosure is not limited thereto, and the second foreign matter discharge port 416 may be formed in various portions of the standby station 410.

In one or more embodiments, the second foreign matter transfer pipe 432 may connect the interior of the standby station 410 and the collector 434. For example, the second foreign matter transfer pipe 432 may communicate with the second foreign matter discharge port 416. When the standby station 410 and the function station 420 are coupled, an end of the second foreign matter transfer pipe 432 may be aligned with the second foreign matter discharge port 416 to communicate with each other so that a fluid may move. Accordingly, the second foreign matter transfer pipe 432 may provide a movement path of the foreign matter directed from the second foreign matter discharge port 416 toward the collector 434.

In one or more embodiments, the collector 434 may collect the foreign matter guided from the first foreign matter transfer pipe 232. In addition, the collector 434 may collectively collect the foreign matter guided from the second foreign matter transfer pipe 432. Thereafter, the foreign matter collected by the collector 434 may be subjected to subsequent processing (e.g., dehydration, sealing, etc.).

Through the above-described configuration, the standby station 410 may frequently maintain cleanliness of the standby space 114 using the vacuum 414 without coupling the function station 420. Accordingly, a simple cleaning operation that does not require coupling of the function station 420 may be possible, and flexibility and efficiency of the pipeline maintenance apparatus 40 may be increased.

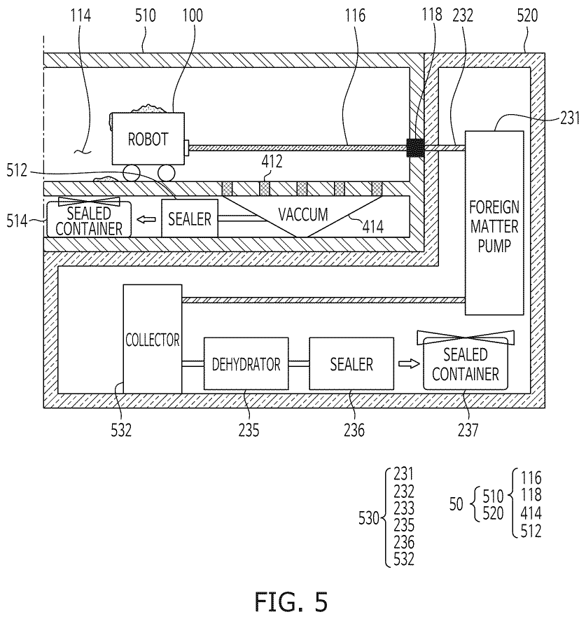

FIG. 5 is a diagram for explaining an example of a pipeline maintenance apparatus 50 for semiconductor facilities according to one or more embodiments of the present disclosure.

The pipeline maintenance apparatus 50 may include a robot 100, a standby station 510, and a function station 520. In one or more embodiments, the standby station 510 may include a foreign matter discharge pipe 116, a first foreign matter discharge port 118, a vacuum 414, and a sealer 512. In addition, the function station 520 may include a foreign matter processor 530 for processing foreign matter, and the foreign matter processor 530 may include a plurality of function units. For example, the foreign matter processor 530 may include the foreign matter pump 231, the first foreign matter transfer pipe 232, a collector 532, the dehydrator 235, and the sealer 236. The standby station 510 of FIG. 5 may further include a suction port 412, the vacuum 414, and the sealer 512 in the standby station 210 of FIG. 2. The foreign matter processor 530 of FIG. 5 may not include the vacuum, unlike the foreign matter processor 230 of FIG. 2. The standby station 510 may include the vacuum 414. Hereinafter, in the description of FIG. 5, contents overlapping with those of FIGS. 1 to 4 will be omitted or briefly described.

In one or more embodiments, the sealer 512 included in the standby station 510 may seal the foreign matter sucked by the vacuum 414. Referring to FIG. 5, the sealer 512 may be disposed at a rear end of the vacuum 414 and may receive the foreign matter sucked by the vacuum 414. In addition, the sealer 512 may be disposed in a separate space separated from a standby space 114 inside the standby station 510 together with the vacuum 414. However, the disclosure is not limited thereto, and the vacuum 414 and/or the sealer 512 may be disposed in the standby space 114.

In one or more embodiments, the sealer 512 may form a sealed container 514 by sealing the foreign matter in a foreign matter container. The sealer 512 may dispose the sealed container 514 in a separate space inside the standby station 510. For example, after the standby station 510 is separated from the function station 520, a worker may discharge the sealed container 514. As another example, the standby station 510 may include a discharge device, and the discharge device may discharge the sealed container 514 to the outside of the standby station 510.

Through the above-described configuration, the standby station 510 may frequently maintain cleanliness of the standby space 114 using the vacuum 414 and the sealer 512 without coupling the function station 520. In addition, the standby station 510 may safely process a relatively large amount of foreign matter through the sealer 512 without coupling the function station 520. Accordingly, flexibility and efficiency of the pipeline maintenance apparatus 50 may be increased.

FIGS. 6 to 9 are diagrams for explaining a sealer according to one or more embodiments of the present disclosure. The sealer may be included in a foreign matter processor (e.g., the foreign matter processor 230 of FIG. 3) of a standby station (e.g., the standby station 510 of FIG. 5) or a function station (e.g., the function station 220 of FIG. 2). The sealer may inject foreign matter into a foreign matter container 610 and may seal the foreign matter container 610.

In one or more embodiments, an opening may be formed at one side of the foreign matter container 610, and the foreign matter may be injected through the opening. An accommodation space may be formed inside the foreign matter container 610, and foreign matter FM may be accommodated in the accommodation space of the foreign matter container 610. The foreign matter container 610 in which the foreign matter FM is accommodated may be sealed by a sealing cap 710. For example, the sealing cap 710 may be inserted into the opening of the foreign matter container 610 to seal the foreign matter container 610.

Referring to FIG. 6, a plurality of foreign matter containers 610 in the sealer may be arranged in a circular shape. For example, the plurality of foreign matter containers 610 may be disposed in a circular frame 600 of the sealer. The plurality of foreign matter containers 610 may be disposed at substantially the same distance from a center of the circular frame 600.

In one or more embodiments, the sealer may include an injection pipe 630 and an opener 620. The injection pipe 630 may inject the foreign matter FM provided to the sealer into the foreign matter container 610. The opener 620 may seal the opening of the foreign matter container 610 with the sealing cap 710 or may release sealing of the sealing cap 710.

In one or more embodiments, the sealer may include a first support part 622 that supports the opener 620 and a second support part 624 that supports the injection pipe 630. For example, one end of the first support part 622 may be fixed to a central axis RA, and the first support part 622 may extend in a radial direction. The opener 620 may be disposed at the other end of the first support part 622. In addition, one end of the second support part 624 may be fixed to the central axis RA, and the second support part 624 may extend in the radial direction. The injection pipe 630 may be disposed at the other end of the second support part 624. A foreign matter injection direction of the injection pipe 630 may be parallel to a direction perpendicular to the radial direction of the second support part 624.

In one or more embodiments, openings of the plurality of foreign matter containers 610 may be disposed on one side of the circular frame 600. The openings of the plurality of foreign matter containers 610 may be disposed on a plane perpendicular to a first direction D1. The opener 620 may be disposed parallel to the first direction D1 and may move perpendicular to the openings of the plurality of foreign matter containers 610. The foreign matter injection direction of the injection pipe 630 may be parallel to the first direction D1.

In one or more embodiments, a center of the circular frame 600 may correspond to the central axis RA of the first support part 622 and the second support part 624. The first support part 622 and the second support part 624 may rotate based on the central axis RA. Accordingly, by rotating the first support part 622 and the second support part 624, the opener 620 and the injection pipe 630 disposed in the first support part 622 and the second support part 624 may be respectively disposed on the openings of each foreign matter container 610.

In one or more embodiments, the sealer may include a connection part 640 that connects the opener 620 and the injection pipe 630. The opener 620 and the injection pipe 630 may be integrally rotated about the central axis RA by the connection part 640. Referring to FIG. 6, the opener 620 may be disposed on the foreign matter container 610. When the first support part 622 and the second support part 624 are rotated by a certain angle, the injection pipe 630 may be disposed on the corresponding foreign matter container 610. Thereafter, when the first support part 622 and the second support part 624 are rotated by a certain angle in the opposite direction, the opener 620 may again be disposed on the corresponding foreign matter container 610. In addition, when the first support part 622 and the second support part 624 are rotated by different certain angles, the opener 620 or the injection pipe 630 may be disposed on another foreign matter container 610. In this way, the opener 620 and the injection pipe 630 may be disposed on each foreign matter container 610 arranged on the circular frame 600.

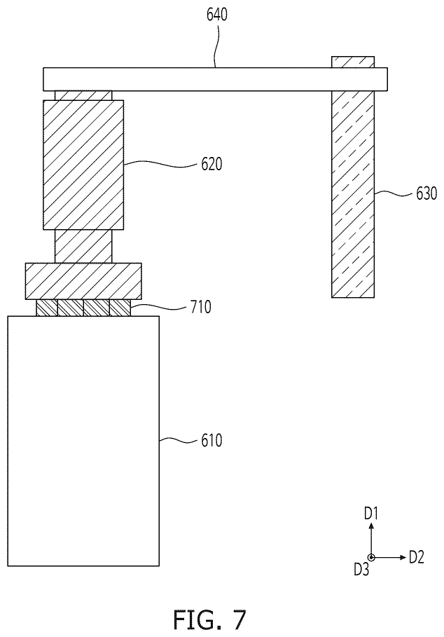

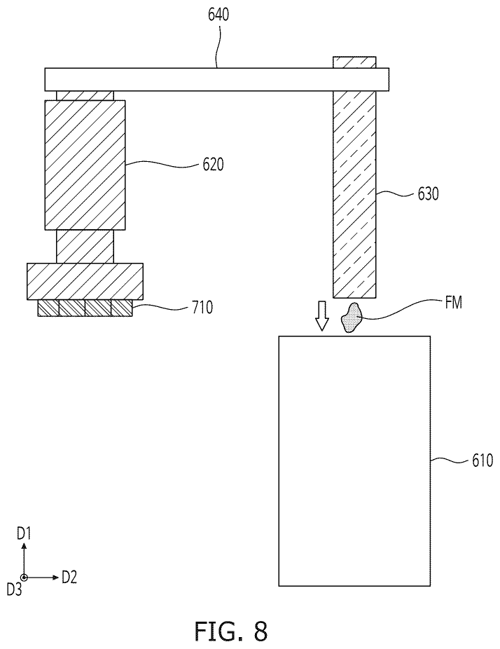

A process of injecting the foreign matter into one foreign matter container 610 will be described with reference to FIGS. 7 and 8.

Referring to FIG. 7, a target foreign matter container 610 into which the foreign matter FM is to be injected may be designated. The first support part 622 and the second support part 624 may rotate based on the central axis RA, and the opener 620 may be located on the sealing cap 710 of the target foreign matter container 610.

An opening of the target foreign matter container 610 may be sealed by the sealing cap 710. The opener 620 may move in a direction opposite to the first direction D1 to be coupled to the sealing cap 710. For example, the opener 620 may contact the sealing cap 710. Thereafter, the opener 620 may be coupled to the sealing cap 710 by adsorbing the sealing cap 710 with a vacuum pressure. The opener 620 coupled to the sealing cap 710 may move in the first direction D1 to separate the sealing cap 710 from the foreign matter container 610. Accordingly, the opening of the foreign matter container 610 may be in an open state.

In a state in which the opener 620 is coupled to the sealing cap 710, the first support part 622 and the second support part 624 may rotate about the central axis RA so that the injection pipe 630 is positioned over the opening of the target foreign matter container 610. Referring to FIG. 8, as the first support part 622 and the second support part 624 rotate about the central axis RA, the opener 620 and the injection pipe 630 can rotate on a plane perpendicular to the first direction D1.

In a state in which the injection pipe 630 is aligned on the opening of the foreign matter container 610, the injection pipe 630 may inject the foreign matter FM into the foreign matter container 610. The injection pipe 630 may inject a predetermined amount (e.g., weight, volume) of the foreign matter FM into the foreign matter container 610. After injection of the foreign matter FM is completed, the first support part 622 and the second support part 624 may again rotate based on the central axis RA so that the opener 620 is disposed on the opening of the foreign matter container 610. The opener 620 coupled to the sealing cap 710 may move in a direction opposite to the first direction D1 to couple the sealing cap 710 to the foreign matter container 610. The sealing cap 710 may seal the opening of the foreign matter container 610 into which the foreign matter FM is injected.

In one or more embodiments, coupling of the foreign matter container 610 and the sealing cap 710 may be achieved by mechanical coupling (e.g., screw coupling, fit coupling, etc.). For example, a thread corresponding to each other may be formed on an inner surface of the opening of the foreign matter container 610 and an outer surface of the sealing cap 710. The opener 620 may include a driving motor that grips the sealing cap 710 and rotates the sealing cap 710 based on an axis parallel to the first direction D1 (e.g., a central axis of the opener 620). The opener 620 may fasten or separate the sealing cap 710 to and from the foreign matter container 610 by rotating clockwise or counterclockwise.

In one or more embodiments, the sealer may include various sensors that communicate with a controller (e.g., the controller 190 of FIG. 1). For example, a sensor that measures a weight of each foreign matter container 610 may be disposed at a lower portion of the circular frame 600 (e.g., a portion supporting each foreign matter container 610 in the circular frame 600). The controller may monitor the weight measured from the sensor. The controller may determine whether a target injection amount of the foreign matter FM is reached based on the measured weight. The controller may stop injection of the foreign matter FM of the injection pipe 630 based on a determination result (e.g., closing a valve provided in the injection pipe 630). Thereafter, the controller may seal the foreign matter container 610 using the opener 620. As another example, the sealer may include an optical sensor for measuring positions of the opener 620 and the injection pipe 630. The controller may align the positions of the opener 620 and the injection pipe 630 based on a measurement result of the optical sensor.

The foreign matter FM may be injected, and the sealed foreign matter container 610 may be processed in various ways. In an example, the sealed foreign matter container 610 may be disposed in the sealer. In another example, the sealed foreign matter container 610 may be disposed in a function station. In another example, the sealed foreign matter container 610 may be discharged to the outside of the function station.

FIG. 9 is a diagram for explaining an example of a pipeline maintenance apparatus 90 for semiconductor facilities according to one or more embodiments of the present disclosure. The pipeline maintenance apparatus 90 may include a robot 100, a standby station 910, and a function station 920. Unlike the pipeline maintenance apparatus 10 of FIG. 1, the pipeline maintenance apparatus 90 may not include a foreign matter processor and an opener/closer.

In one or more embodiments, the robot 100 may process the foreign matter removed from a pipeline SEP in various ways. For example, the robot 100 may include a foreign matter container capable of accommodating the removed foreign matter therein and may temporarily store the foreign matter in the foreign matter container. Thereafter, the foreign matter container in which the foreign matter is accommodated may be separated from the robot 100 and discharged. As another example, the robot 100 may discharge the foreign matter to the outside of the standby station 910 without passing through the function station 920. For example, a pipeline member connected to an external device (e.g., a foreign matter pump, a vacuum, a collector, etc.) may penetrate the standby station 910 and may be connected to the robot 100. The foreign matter removed from the robot 100 may be discharged to the outside of the standby station 910 along the pipeline member.

In one or more embodiments, the robot 100 may be supplied with a resource used for removing the foreign matter from the outside of the standby station 910. For example, the robot 100 may be supplied with water, a cleaning liquid, air, etc. required for removing the foreign matter. The robot 100 may be supplied with power for performing an operation. The robot 100 may be provided with a communication signal for communicating with a controller (e.g., the controller 190 of FIG. 1).

In one or more embodiments, the standby station 910 may include a first resource transfer pipe 912 configured to provide a resource to the robot 100. The first resource transfer pipe 912 may be disposed in the standby station 910. In addition, the standby station 910 may include a resource connector 914 formed penetrating the standby station 910 such that the resource is supplied from the outside of the standby station 910. For example, one end of the first resource transfer pipe 912 may be connected to the resource connector 914. The other end of the first resource transfer pipe 912 may be connected to the robot 100. As another example, at least a portion of a second resource transfer pipe 922 that provides a resource to the robot 100 may be disposed in the function station 920. The second resource transfer pipe 922 may be inserted into the resource connector 914 to be connected to the robot 100. In this case, the first resource transfer pipe 912 may be a resource transfer pipe integrated with the second resource transfer pipe 922 located inside the standby station 910. Accordingly, the resource supplied from the outside of the standby station 910 through the resource connector 914 may be supplied to the robot 100 through the first resource transfer pipe 912.

In one or more embodiments, one end of the first resource transfer pipe 912 may be docked with the robot 100. For example, the robot 100 may include a docking port. One end of the first resource transfer pipe 912 may be docked to or undocked from the docking port of the robot 100. In another embodiment, the other end of the first resource transfer pipe 912 may be connected to the resource connector 914. The other end of the first resource transfer pipe 912 may be docked and coupled to the resource connector 914.

In one or more embodiments, the standby station 910 may include a docking device configured to control docking of the first resource transfer pipe 912. For example, the docking device may include a gripper for gripping the first resource transfer pipe 912, a driving unit (e.g., a multi-joint robot arm) connected to the gripper, and the like. The gripper may grip the first resource transfer pipe 912, and the driving unit may move the gripper gripping the first resource transfer pipe 912 to a designated position. For example, the driving unit may align one end of the first resource transfer pipe 912 with the docking port of the robot 100 or a docking port of the resource connector 914. As another example, the driving unit may separate the other end of the first resource transfer pipe 912 from the docking port of the robot 100 or the docking port of the resource connector 914 and move the other end to a standby position.

In one or more embodiments, the function station 920 may include the second resource transfer pipe 922 configured such that a resource used for removing the foreign matter by the pipeline maintenance robot 100 moves to the pipeline maintenance robot 100. The second resource transfer pipe 922 may be disposed in the function station 920. In addition, the function station 920 may include a reel 930 that accommodates the second resource transfer pipe 922 and guides movement of the second resource transfer pipe 922. The reel 930 may include a storage device 932 that accommodates the second resource transfer pipe 922. For example, the storage device 932 may accommodate the second resource transfer pipe 922 through a hose reel, a cable drum, or the like. The storage device 932 may include a driving motor coupled to a hose reel, a manual rotation device, etc., and the second resource transfer pipe 922 may be discharged while being unwound and may be accommodated while being wound.

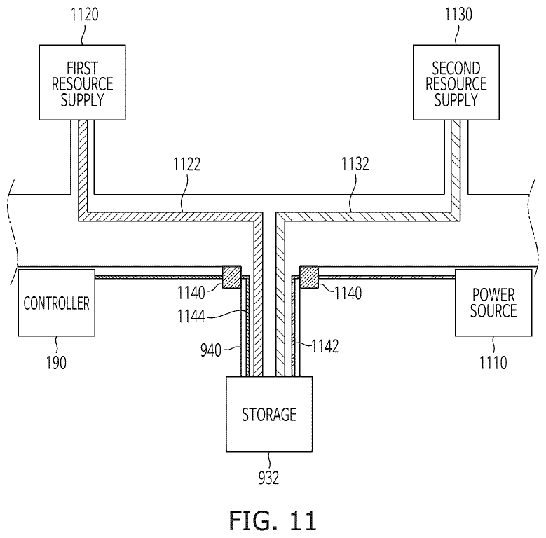

In one or more embodiments, a third resource transfer pipe 940 may be located at an entry portion of the storage device 932. The third resource transfer pipe 940 may be located to penetrate the function station 920. The third resource transfer pipe 940 may be connected to a resource transfer pipe accommodated in the storage device 932. In addition, the third resource transfer pipe 940 may be connected to a resource supply device to be supplied with a resource. A specific structure of the third resource transfer pipe 940 will be described in detail with reference to FIG. 11.

In one or more embodiments, the second resource transfer pipe 922 may be located at a discharge part of the storage device 932. The second resource transfer pipe 922 may be connected to the resource connector 914 or may be located to penetrate the resource connector 914. The second resource transfer pipe 922 may be connected to the resource transfer pipe accommodated in the storage device 932. The resource supplied to the resource supply device may be supplied to the robot 100 via the third resource transfer pipe 940, the second resource transfer pipe 922, and the first resource transfer pipe 912.

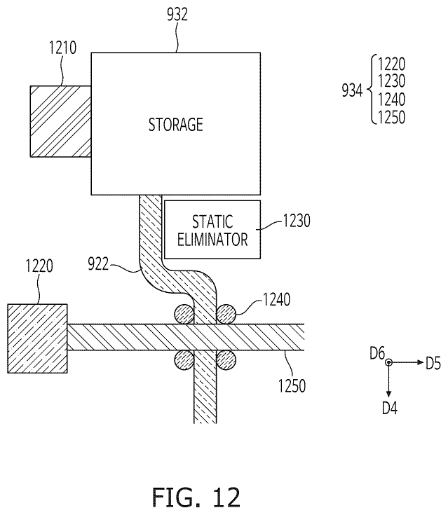

In one or more embodiments, the reel 930 may include a guide 934 disposed at the discharge part of the storage device 932 and configured to guide transfer of the second resource transfer pipe 922. The guide 934 may guide the second resource transfer pipe 922 disposed at the discharge part of the storage device 932 so as not to be tangled. A specific structure of the guide 934 will be described in detail with reference to FIGS. 11 and 12.

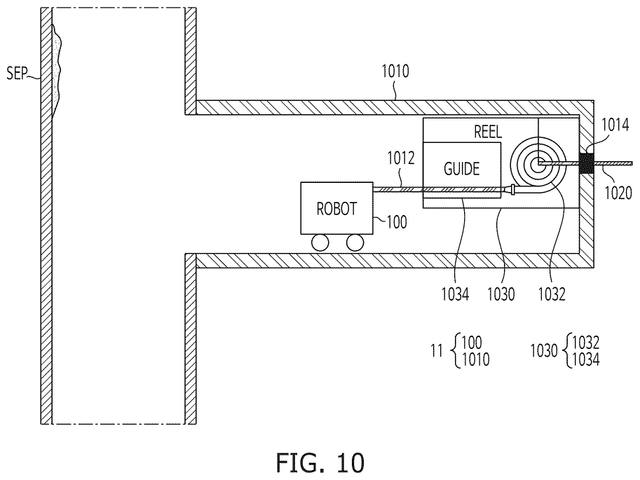

FIG. 10 is a diagram for explaining an example of a pipeline maintenance apparatus 11 for semiconductor facilities according to one or more embodiments of the present disclosure. The pipeline maintenance apparatus 11 may include a robot 100 and a standby station 1010. Unlike the standby station 910 of FIG. 9, the standby station 1010 of FIG. 10 may include a reel 1030. Hereinafter, in the description of FIG. 10, contents overlapping with those described in FIG. 9 will be omitted or briefly described.

In one or more embodiments, the standby station 1010 may include a first resource transfer pipe 1012 configured to provide a resource to the robot 100. One end of the first resource transfer pipe 1012 may be docked with the robot 100. For example, the robot 100 may include a docking port. One end of the first resource transfer pipe 1012 may be docked to or undocked from the docking port of the robot 100. Accordingly, the resource supplied from the outside of the standby station 1010 through a resource connector 1014 may be supplied to the robot 100 through the first resource transfer pipe 1012.

In one or more embodiments, the reel 1030 may include a storage device 1032 that accommodates the first resource transfer pipe 1012. The first resource transfer pipe 1012 may be located at a discharge part of the storage device 1032. The reel 1030 may include a guide 1034 disposed at the discharge part of the storage device 1032 and configured to guide transfer of the first resource transfer pipe 1012.

In one or more embodiments, the standby station 1010 may include a resource connector 1014 formed through the standby station 1010 such that a resource is supplied from the outside of the standby station 1010. In one example, the second resource transfer pipe 1020 may be positioned at an entry portion of a storage device 1032 through the resource connector 1014, and the resource transfer pipe accommodated in the storage device 1032 may be connected to the second resource transfer pipe 1020. In another example, the second resource transfer pipe 1020 may be connected to the resource connector 1014, and the resource connector 1014 may be connected to the resource transfer pipe located at the entry portion of the storage device 1032. Accordingly, the resource supplied through the resource connector 1014 may move to the robot 100 via the resource transfer pipe 1012 disposed in the standby station 1010.

In one or more embodiments, one end of the second resource transfer pipe 1020 may be detachably docked with the resource connector 1014. Accordingly, the second resource transfer pipe 1020 may be connected to or disconnected from the resource connector 1014.

FIG. 11 is a diagram for explaining an example of a resource transfer pipe 940 located at an entry portion of a storage device 932 according to one or more embodiments of the present disclosure. The resource transfer pipe 940 may be located at the entry portion of the storage device 932.

In one or more embodiments, the resource transfer pipe 940 may include a first sub-resource transfer pipe 1122 and a second sub-resource transfer pipe 1132. The first sub-resource transfer pipe 1122 may be connected to a first resource supply 1120. The first sub-resource transfer pipe 1122 may be supplied with a first resource (e.g., water, a cleaning liquid, air, etc.) from the first resource supply 1120. The first resource may move along the first sub-resource transfer pipe 1122. The second sub-resource transfer pipe 1132 may be connected to a second resource supply 1130. The second sub-resource transfer pipe 1132 may be supplied with a second resource (e.g., water, a cleaning liquid, air, etc.) from the second resource supply 1130. The second resource may move along the second sub-resource transfer pipe 1132.

In one or more embodiments, the resource transfer pipe 940 may be in the form of a composite pipe including a plurality of sub-resource transfer pipes 1122 and 1132 therein. For example, the resource transfer pipe 940 may include the first sub-resource transfer pipe 1122 and the second sub-resource transfer pipe 1132 disposed inside an outer shell surrounding the outside. In FIG. 11, two sub-resource transfer pipes 1122 and 1132 are illustrated, but the disclosure is not limited thereto. For example, the resource transfer pipe 940 may include a single sub-resource transfer pipe or three or more sub-resource transfer pipes.

In one or more embodiments, the resource transfer pipe 940 may include a power line 1142 and/or a signal line 1144. The resource transfer pipe 940 may include the power line 1142 connected to a power source 1110. In addition, the resource transfer pipe 940 may include the signal line 1144 connected to the controller 190. Referring to FIG. 11, the power line 1142 and the signal line 1144 are illustrated as separate lines, but the disclosure is not limited thereto. For example, the power line 1142 and the signal line 1144 may be configured together in one line.

In one or more embodiments, the resource transfer pipe 940 may include a rotary connection device 1140. For example, the rotary connection device 1140 may include a slip-ring. The rotary connection device 1140 may prevent the power line 1142 and/or the signal line 1144 from being tangled when the storage device 932 rotates. For example, the rotary connection device 1140 may be installed on a rotation axis of the storage device 932. Some of the power line 1142 and/or the signal line 1144 may be connected to a fixing part of the rotary connection device 1140, and the other of the power line 1142 and/or the signal line 1144 may be connected to a rotating part of the rotary connection device 1140. Due to the rotary connection device 1140, even when the storage device 932 rotates, power and a signal of the power line 1142 and/or the signal line 1144 may be stably provided.

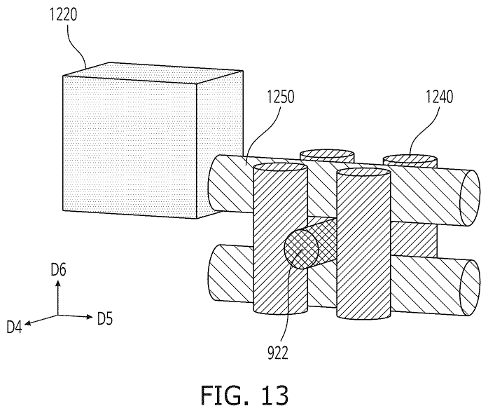

FIGS. 12 and 13 are diagrams for explaining an example of a guide 934 according to one or more embodiments of the present disclosure. In one or more embodiments, the guide 934 may include a motor 1220, an static eliminator 1230, a pair of idler rollers 1240, and a pair of feeder rollers 1250. The guide 934 shown in FIGS. 12 and 13 may be understood in the same manner also with respect to the guide 1034 of FIG. 10.

In one or more embodiments, the guide 934 may be disposed at a discharge part of the storage device 932. The storage device 932 may be coupled to a driving motor 1210. For example, the storage device 932 may include a hose reel, and the driving motor 1210 may rotate the hose reel. The driving motor 1210 may unwind or wind the resource transfer pipe accommodated in the storage device 932.

In one or more embodiments, the static eliminator 1230 may remove static electricity of a resource transfer pipe 922 disposed at the discharge part of the storage device 932. For example, the static eliminator 1230 may include an ionizer that generates ions. Ions generated by the ionizer may neutralize static electricity accumulated on a surface of the resource transfer pipe 922. As another example, the static eliminator 1230 may include a grounded brush. The brush may discharge static electricity by contacting the surface of the resource transfer pipe 922.

In one or more embodiments, the idler roller 1240 may be arranged as a pair to guide transfer of the resource transfer pipe 922. For example, the pair of idler rollers 1240 may be disposed to face each other with a transfer path of the resource transfer pipe 922 interposed therebetween. Referring to FIG. 12, the transfer path may extend in a fourth direction D4. The idler roller 1240 may freely rotate about a first rotation axis. The first rotation axis may intersect the fourth direction D4. For example, the pair of idler rollers 1240 may contact left and right surfaces of the resource transfer pipe 922 and may align a position of the resource transfer pipe 922. Through this, the pair of idler rollers 1240 may prevent the resource transfer pipe 922 from moving in left and right directions (e.g., a fifth direction D5) and may align the position so as to move along the transfer path (e.g., the fourth direction D4).

In one or more embodiments, the feeder roller 1250 may be arranged as a pair to guide transfer of the resource transfer pipe 922. For example, the pair of feeder rollers 1250 may be disposed to face each other with the transfer path of the resource transfer pipe 922 interposed therebetween. Referring to FIG. 12, the transfer path may extend in the fourth direction D4. The feeder roller 1250 may be driven to rotate about a second rotation axis. The second rotation axis may intersect the fourth direction D4. For example, the pair of feeder rollers 1250 may be connected to the rotary motor 1220 and may be driven to rotate by a driving force of the rotary motor 1220. The pair of feeder rollers 1250 may contact upper and lower surfaces of the resource transfer pipe 922. The pair of feeder rollers 1250 may rotate under control of the rotary motor 1220 to provide a driving force for pushing or pulling the resource transfer pipe 922 from the storage device 932. Through this, a moving speed of the resource transfer pipe 922 may be controlled, and the resource transfer pipe 922 may be transferred (e.g., transferred in the fourth direction D4).

FIG. 14 is a diagram illustrating an example of a pipeline maintenance apparatus 14 for semiconductor facilities according to one or more embodiments of the present disclosure. The pipeline maintenance apparatus 14 may include a robot 100 and a standby station 1400. Hereinafter, in the description of FIG. 14, contents overlapping with those described above in FIG. 1, etc. will be omitted or briefly described.

In one or more embodiments, the standby station 1400 may be provided on the outside of a pipeline SEP to provide an access passage 112 of the robot 100. For example, an idle robot 100 may wait in a standby space 114. When the robot 100 receives a pipeline SEP entry command, the robot 100 may enter the interior of the pipeline SEP through the access passage 112.

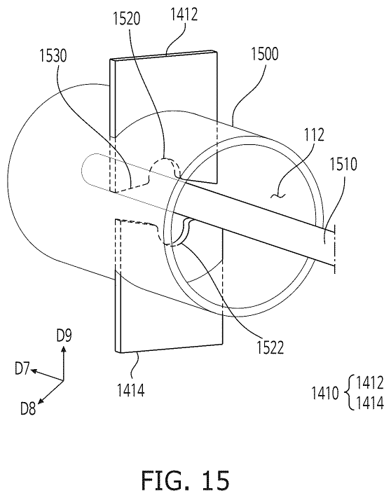

In one or more embodiments, the standby station 1400 may include an opener/closer 1410 that opens or closes the access passage 112 of the pipeline maintenance robot 100. The opener/closer 1410 may selectively communicate or block between the standby space 114 and the interior of the pipeline SEP. The opener/closer 1410 may include a first opening and closing door 1412 and a second opening and closing door 1414 that move while facing each other. However, the disclosure is not limited thereto, and the opener/closer 1410 may include a single opening and closing door or three or more opening and closing doors. A specific structure of the opening and closing doors 1412 and 1414 will be described in detail with reference to FIGS. 15 to 17.

In one or more embodiments, the standby station 1400 may include a static eliminator 1420. The static eliminator 1420 may be disposed in the standby space 114 (e.g., the standby space 114 adjacent to the access passage 112) or the access passage 112. The static eliminator 1420 may remove static electricity generated on a surface of the robot 100. For example, the static eliminator 1420 may include an ionizer that generates ions. Ions generated by the ionizer may neutralize static electricity accumulated on the surface of the robot 100. As another example, the static eliminator 1420 may include a grounded brush. The brush may discharge static electricity by contacting the surface of the robot 100.

In one or more embodiments, the opener/closer 1410 may be opened or closed at a specific timing based on control of a controller (e.g., the controller 190 of FIG. 1). For example, while the robot 100 is waiting in the standby space 114 or performing work inside the pipeline SEP, the opener/closer 1410 may close the access passage 112. Accordingly, the standby space 114 and an internal space of the pipeline SEP may be isolated from each other. In addition, when the robot 100 enters the pipeline SEP or returns to the standby space 114, the opener/closer 1410 may open the access passage 112. When the robot 100 passes through the access passage 112, the opener/closer 1410 may close the access passage 112.

In one or more embodiments, the opener/closer 1410 may independently maintain an environment of the standby space 114 and an environment inside the pipeline SEP. For example, in a state in which the opener/closer 1410 is closed, the environment (e.g., pressure, temperature, etc.) of the standby space 114 may be adjusted. In an example, pressure of the standby space 114 may be adjusted so that the pressure of the standby space 114 corresponds to pressure inside the pipeline SEP so that the robot 100 enters the interior of the pipeline SEP.

In one or more embodiments, the opener/closer 1410 may be implemented in a function station. For example, the function station may include the opener/closer 1410 and may be mounted between the outside of the pipeline SEP and the standby station 1400. The corresponding function station may be selectively coupled to or separated from the standby station 1400. Depending on a use environment of a semiconductor facility, the standby station 1400 on which the corresponding function station is mounted may be provided on the outside of the pipeline SEP, or the standby station 1400 on which the corresponding function station is not mounted may be provided on the outside of the pipeline SEP.

FIGS. 15 to 17 are diagrams for explaining an example of the opener/closer 1410 according to one or more embodiments of the present disclosure. The standby station 1500 may provide an access passage 112. The opener/closer 1410 may be located in the access passage 112 of the standby station 1500.

Referring to FIG. 15, a process in which the opener/closer 1410 is closed after a robot passes through the access passage 112 and enters the interior of a pipeline is illustrated. The robot may move in a seventh direction D7 from a standby space toward the interior of the pipeline. The robot may be connected to a pipeline member 1510. For example, the pipeline member 1510 may include a foreign matter discharge pipe (e.g., the foreign matter discharge pipe 116 of FIG. 1) through which foreign matter removed by the robot is discharged, a resource transfer pipe (e.g., the first resource transfer pipe 912 of FIG. 9) through which a resource required for removing the foreign matter of the robot moves, and the like.

In one or more embodiments, the opener/closer 1410 may include a first opening and closing door 1412 and a second opening and closing door 1414. The first opening and closing door 1412 may extend in a direction opposite to a ninth direction D9 intersecting the seventh direction D7. The second opening and closing door 1414 may extend in the ninth direction D9. The first opening and closing door 1412 and the second opening and closing door 1414 may be disposed in parallel.

In one or more embodiments, the opening and closing doors 1412 and 1414 may include a material suitable for a semiconductor facility environment. For example, the opening and closing doors 1412 and 1414 may include stainless steel, an aluminum alloy, coated plastic, or the like. Accordingly, the opening and closing doors 1412 and 1414 may have chemical resistance to a corrosive gas and may have rigidity required for an opening and closing operation.

In one or more embodiments, the opening and closing doors 1412 and 1414 may move in the ninth direction D9 to open or close the access passage 112. For example, to close the access passage 112, the first opening and closing door 1412 may move in a direction opposite to the ninth direction D9, and the second opening and closing door 1414 may move in the ninth direction D9.

In one or more embodiments, grooves 1520 and 1522 may be formed at one specific end of the opening and closing doors 1412 and 1414. For example, the first opening and closing door 1412 may be disposed at an upper portion (e.g., a portion disposed in the ninth direction D9) of the access passage 112, and the first groove 1520 may be formed at a lower end of the first opening and closing door 1412. The second opening and closing door 1414 may be disposed at a lower portion (e.g., a portion disposed in a direction opposite to the ninth direction D9) of the access passage 112, and the second groove 1522 may be formed at an upper end of the second opening and closing door 1414.

In one or more embodiments, one end of the opening and closing doors 1412 and 1414 in which the grooves 1520 and 1522 are formed may be formed to be inclined toward the grooves 1520 and 1522. For example, a lower end of the first opening and closing door 1412 may include an inclined portion 1530 leading to the first groove 1520. When the opening and closing doors 1412 and 1414 are closed, the inclined portion 1530 may contact the pipeline member 1510 and may guide the pipeline member 1510 toward the center of the grooves 1520 and 1522. Accordingly, the pipeline member 1510 may be safely used without being caught by the opening and closing doors 1412 and 1414.

In one or more embodiments, a low-friction member may be mounted on the inclined portion 1530. For example, the low-friction member may include a bearing. The low-friction member may be rotatably installed on a surface of the inclined portion 1530. When the opening and closing doors 1412 and 1414 are closed, the pipeline member 1510 may move along the low-friction member. Accordingly, a risk of wear and damage of the pipeline member 1510 may be reduced.

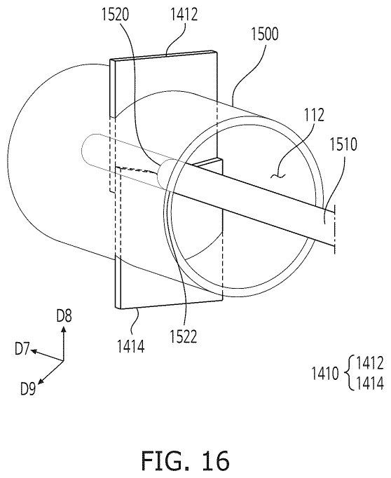

Referring to FIG. 16, a state in which the robot has entered the interior of the pipeline through the access passage 112 and the access passage 112 is subsequently blocked may be illustrated. The first groove 1520 and the second groove 1522 may engage with each other to form a through-hole through which the pipeline member 1510 can pass. That is, the pipeline member 1510 connected to the robot can pass through the opener/closer 1410 even when the access passage 112 is closed. Further, the standby space and the interior of the pipeline may be isolated from each other by the first opening and closing door 1412, the second opening and closing door 1414, and the pipeline member 1510. Accordingly, even though the standby space and the interior of the pipeline are isolated, the pipeline member 1510 required for the operation of the robot 100 can slide and move in a longitudinal direction through the through-hole so as to be supplied into the pipeline or recovered to the standby space.

In one or more embodiments, the opener/closer 1410 may further include a sealing member. For example, the sealing member may be located on a surface on which the first opening and closing door 1412 and the second opening and closing door 1414 contact each other. For example, the sealing member may include an elastic member including a gasket, an O-ring, or the like. The sealing member may block a gap of the opener/closer 1410 in a closed state to increase airtightness.

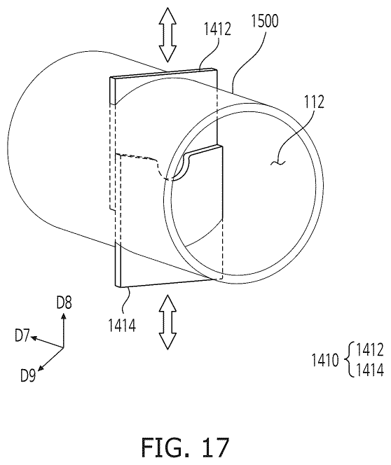

Referring to FIG. 17, a state in which the robot does not enter the interior of the pipeline and the access passage 112 is blocked is illustrated. For example, the opening and closing doors 1412 and 1414 may be closed while the robot is waiting in the standby space so that the access passage 112 is blocked. The opener/closer 1410 may block the access passage 112 to seal the standby space. For example, the first opening and closing door 1412 and the second opening and closing door 1414 may move to an overlapping position and may be closed. Through overlapping of the first opening and closing door 1412 and the second opening and closing door 1414, the through-hole formed by the first groove 1520 and the second groove 1522 may also be blocked.

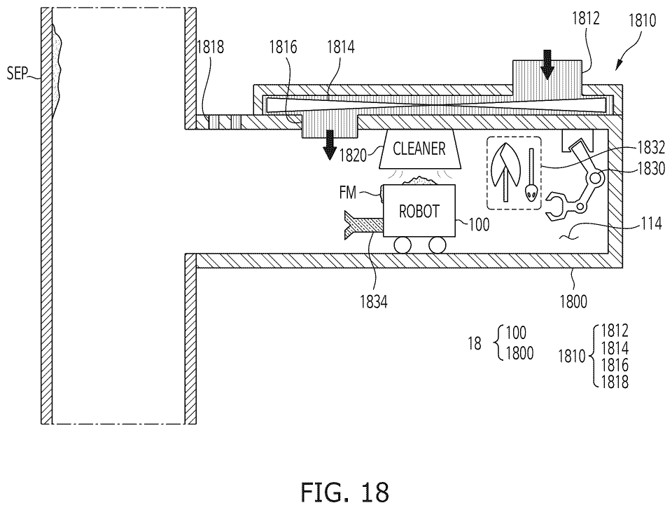

FIG. 18 is a diagram for explaining an example of a pipeline maintenance apparatus 18 for semiconductor facilities according to one or more embodiments of the present disclosure. The pipeline maintenance apparatus 18 may include a robot 100 and a standby station 1800. Hereinafter, in the description of FIG. 18, contents overlapping with those described above in FIG. 1, etc. will be omitted or briefly described.

In one or more embodiments, an air circulation device 1810 may circulate air in a standby space 114. The air circulation device 1810 may include air passages 1812, 1816, and 1818 and an air suction fan 1814. In an example, the air circulation device 1810 may be installed at one side of the standby station 1800. In another example, the air circulation device 1810 may be implemented as a function station, and the corresponding function station may be selectively coupled to or separated from the standby station 1800.

In one or more embodiments, external air may be introduced into a first air passage 1812. The first air passage 1812 may be formed on one side surface of the air circulation device 1810. Referring to FIG. 18, one first air passage 1812 is illustrated as being formed in the air circulation device 1810, but the disclosure is not limited thereto. For example, the number and position of the first air passages 1812 may be variously determined.

In one or more embodiments, a second air passage 1816 that communicates the air circulation device 1810 with the interior of the standby station 1800 may be formed. In addition, a third air passage 1818 penetrating one surface of the standby station 1800 may be formed.

In one or more embodiments, the air suction fan 1814 may control an air flow in the standby space 114. For example, the air suction fan 1814 may introduce external air into the standby space 114 or maintain circulation of air inside the standby space 114. For example, the air suction fan 1814 may induce external air introduced through the first air passage 1812 to be introduced into the standby space 114 through the second air passage 1816. As another example, the air suction fan 1814 may induce air inside the standby space 114 to flow out through the third air passage 1818 formed penetrating the standby station 1800.

In one or more embodiments, a cleaner 1820 may remove foreign matter attached to a surface of the robot 100. The cleaner 1820 may spray water, air, or the like toward the robot 100 to remove foreign matter, contaminants, etc. attached to the surface of the robot 100. The removed foreign matter, contaminants, etc. may move (e.g., fall) to a bottom of the standby station 1800. The foreign matter, contaminants, etc. disposed on the bottom may be sucked by a vacuum (e.g., the vacuum 233 of FIG. 2).

In an example, the cleaner 1820 may be installed inside the standby station 1800. In another example, the cleaner 1820 may be implemented as a function station, and the corresponding function station may be selectively coupled to or separated from the standby station 1800.

In one or more embodiments, a tool replacer 1830 may mount a cleaning tool 1834 suitable for pipeline maintenance on the robot 100. For example, a controller (e.g., the controller 190 of FIG. 1) may determine the cleaning tool 1834 based on data related to a pipeline (e.g., a type of foreign matter inside the pipeline, etc.). The controller may command the tool replacer 1830 to mount the determined cleaning tool 1834 on the robot 100. When the cleaning tool 1834 is already mounted on the robot 100, the tool replacer 1830 may replace the previously mounted cleaning tool 1834 with the determined cleaning tool 1834. However, the disclosure is not limited thereto, and the tool replacer 1830 may replace various tools mounted on the robot 100 in addition to the cleaning tool 1834.

In an example, the tool replacer 1830 may be installed inside the standby station 1800. In another example, the tool replacer 1830 may be implemented as a function station, and the corresponding function station may be selectively coupled to or separated from the standby station 1800.

In one or more embodiments, the tool replacer 1830 may include a tool storage box 1832. The tool storage box 1832 may include various types of tools. The tool replacer 1830 may dispose the cleaning tool 1834 separated from the robot 100 in the tool storage box 1832. In addition, the tool replacer 1830 may mount the cleaning tool 1834 disposed in the tool storage box 1832 on the robot 100.

In one or more embodiments, the controller may acquire information on a type of a tool stored in the tool storage box 1832. The controller may select one of the cleaning tools 1834 included in the tool storage box 1832 based on information on the type of the cleaning tool 1834. The controller may transmit a command related to the selected cleaning tool 1834 to the tool replacer 1830 based on information on the selected cleaning tool 1834.

FIG. 19 is a diagram for explaining an example of the robot 100 according to one or more embodiments of the present disclosure. The robot 100 may be inserted through an opening (e.g., an inspection port, a small opening, etc.) formed in a pipeline SEP without a standby station and may perform work. For example, the robot 100 may be inserted into the interior through the opening of the pipeline SEP, and the opening may be sealed by a pipeline stopper SP.

In one or more embodiments, the pipeline stopper SP may include a through-hole. A pipeline member 2030 connected to the robot 100 may pass through the pipeline stopper SP through the through-hole of the pipeline stopper SP. For example, the pipeline member 2030 may include a resource transfer pipe, a foreign matter discharge pipe, a power line, a signal line, and the like. However, the disclosure is not limited thereto, and the robot 100 may operate wirelessly inside the pipeline SEP.

In one or more embodiments, the robot 100 may include a plurality of tools to perform various tasks inside the pipeline SEP. For example, the robot 100 may include a cleaning tool 1834 for removing foreign matter FM attached to an inner wall of the pipeline. For example, the cleaning tool 1834 may include a brush, a scraper, or the like. As another example, the robot 100 may include a spray tool 2010 for spraying a fluid such as a cleaning liquid, a neutralizer, or water. The fluid sprayed by the spray tool 2010 may be used to remove foreign matter inside the pipeline. As yet another example, the robot 100 may include a suction tool 2020 that sucks foreign matter. The suction tool 2020 may generate negative pressure to suck the foreign matter FM inside the pipeline SEP.

In one or more embodiments, the robot 100 may include a sensor 2040 for monitoring the interior of the pipeline SEP. For example, the sensor 2040 may include a vision sensor that acquires an image inside the pipeline SEP, a chemical sensor that analyzes a component of the foreign matter FM, a position sensor that generates position information of the robot 100, and the like.

In one or more embodiments, the robot 100 may include a safety device. For example, the spray tool 2010 of the robot 100 may spray a fluid such as water on a body or surface of the robot 100 to remove static electricity from the surface of the robot 100. As another example, the robot 100 may include a ground terminal 2050. The ground terminal 2050 may discharge static electricity generated on the body or surface of the robot 100. A ground line of the ground terminal 2050 may be disposed inside the pipeline member 2030 to maintain grounding.

As described above, by modularizing a standby station with a mobile function station that can be separated therefrom, a pipeline maintenance apparatus that flexibly responds to environmental constraints and different requirements of various industrial sites can be provided.

Although the present disclosure has been described with reference to limited embodiments and drawings, the present disclosure is not limited thereto, and various modifications and variations can be made within the technical spirit of the present disclosure and the equivalent scope of the claims to be described below by those of ordinary skill in the art to which the present disclosure pertains.

What is claimed is:

1. A pipeline maintenance apparatus comprising:
a pipeline maintenance robot configured to move along an interior of a pipeline of a semiconductor facility and to remove foreign matter from the pipeline;
a standby station on an outside of the pipeline, wherein the standby station is configured to provide an access passage for the pipeline maintenance robot and to provide a standby space for the pipeline maintenance robot to wait;
a mobile function station configured to be selectively coupled to or separated from the standby station;
a resource transfer pipe configured to move a resource used for removal of the foreign matter to the pipeline maintenance robot; and
a reel configured to accommodate the resource transfer pipe and to guide a movement of the resource transfer pipe.

2. The pipeline maintenance apparatus of claim 1, wherein the standby station further comprises a resource connector penetrating the standby station,
wherein the resource connector is configured to allow the resource to be supplied from an outside of the standby station,
wherein at least a portion of the resource transfer pipe is in the mobile function station, and
wherein the resource transfer pipe in the mobile function station is in the resource connector and is configured to be connected to the pipeline maintenance robot.

3. The pipeline maintenance apparatus of claim 1, wherein the reel comprises:
a storage configured to accommodate the resource transfer pipe; and
a guide disposed at a discharge part of the storage and configured to guide a transfer of the resource transfer pipe.

4. The pipeline maintenance apparatus of claim 3, wherein the guide comprises:
a pair of idler rollers disposed to face each other with a transfer path of the resource transfer pipe therebetween, wherein the pair of idler rollers extend in a first direction and are configured to freely rotate to align a vertical position of the resource transfer pipe; and
a pair of feeder rollers disposed to face each other with the transfer path therebetween, wherein the pair of feeder rollers extend in a second direction crossing the first direction and are configured to rotate to transfer the resource transfer pipe.

5. The pipeline maintenance apparatus of claim 1, wherein the standby station further comprises a resource connector penetrating the standby station,
wherein the resource connector is configured to allow the resource to be supplied from an outside of the standby station,
wherein the resource transfer pipe is in the standby station, and
wherein the resource supplied through the resource connector moves through the resource transfer pipe.

6. The pipeline maintenance apparatus of claim 1, wherein the standby station comprises a first foreign matter discharge port penetrating the standby station,
wherein the first foreign matter discharge port is configured to allow the foreign matter to be discharged to an outside of the standby station,
wherein the mobile function station comprises a foreign matter processor configured to process the foreign matter removed by the pipeline maintenance robot, and
wherein the foreign matter processor comprises:
a first foreign matter transfer pipe configured to allow the foreign matter to be discharged through the first foreign matter discharge port; and
a collector configured to collect the foreign matter discharged through the first foreign matter transfer pipe.

7. The pipeline maintenance apparatus of claim 6, wherein the foreign matter processor further comprises a first foreign matter pump configured to apply a negative pressure in the first foreign matter transfer pipe to induce a movement of the foreign matter to the collector.

8. The pipeline maintenance apparatus of claim 6, wherein the standby station further comprises:
a foreign matter discharge pipe connected to the first foreign matter discharge port and configured to be selectively coupled to or separated from the pipeline maintenance robot; and
a second foreign matter pump configured to apply a positive pressure in the foreign matter discharge pipe to induce a movement of the foreign matter to the collector.

9. The pipeline maintenance apparatus of claim 6, wherein the foreign matter processor further comprises a dehydrator configured to dehydrate the foreign matter collected by the collector.

10. The pipeline maintenance apparatus of claim 6, wherein the foreign matter processor further comprises a sealer configured to inject the collected foreign matter into a foreign matter container and to seal the foreign matter container.

11. The pipeline maintenance apparatus of claim 10, wherein the sealer comprises:
an injection pipe configured to inject the foreign matter into the foreign matter container; and
an opener configured to be coupled to or separated from a sealing cap and configured to seal or open the foreign matter container, and
wherein the sealing cap is configured to seal an opening of the foreign matter container.

12. The pipeline maintenance apparatus of claim 6, wherein the standby station further comprises a second foreign matter discharge port penetrating the standby station, and
wherein the foreign matter processor further comprises a vacuum configured to suck foreign matter from the standby space through the second foreign matter discharge port.

13. The pipeline maintenance apparatus of claim 6, wherein the standby station further comprises a vacuum configured to suck foreign matter from the standby space.

14. The pipeline maintenance apparatus of claim 13, wherein the standby station further comprises a second foreign matter discharge port penetrating the standby station, wherein the second foreign matter discharge port is configured to allow the foreign matter sucked by the vacuum to be discharged to an outside of the standby station,
wherein the foreign matter processor further comprises a second foreign matter transfer pipe configured to allow the foreign matter to be discharged through the second foreign matter discharge port, and
wherein the collector is further configured to collect the foreign matter discharged through the second foreign matter transfer pipe.

15. The pipeline maintenance apparatus of claim 13, wherein the standby station further comprises a sealer configured to inject the foreign matter sucked by the vacuum into a foreign matter container and to seal the foreign matter container.

16. The pipeline maintenance apparatus of claim 1, wherein the standby station further comprises an opener/closer configured to open or close the access passage of the pipeline maintenance robot, and
wherein the resource transfer pipe connected to the pipeline maintenance robot is configured to pass through the opener/closer in a state in which the access passage is closed.

17. The pipeline maintenance apparatus of claim 16, wherein the opener/closer comprises a door extending in a second direction crossing a first direction facing the pipeline from the standby space, and
wherein the door is configured to move in the second direction to open or close the access passage.

18. The pipeline maintenance apparatus of claim 17, wherein the resource transfer pipe is configured to pass through a groove formed at one end of the door, and
wherein the one end of the door is inclined toward the groove.

19. A pipeline maintenance apparatus comprising:
a pipeline maintenance robot configured to move along an interior of a pipeline of a semiconductor facility, to monitor a state of the pipeline, and to remove foreign matter from the pipeline;
a standby station on an outside of the pipeline, wherein the standby station is configured to provide an access passage for the pipeline maintenance robot and to provide a standby space for the pipeline maintenance robot to wait; and
a mobile function station configured to be selectively coupled to or separated from the standby station,
wherein the standby station comprises a first foreign matter discharge port penetrating the standby station and configured to allow the foreign matter to be discharged to an outside of the standby station, and
wherein the mobile function station comprises:
a first foreign matter transfer pipe configured to allow the foreign matter to be discharged through the first foreign matter discharge port;
a collector configured to collect the foreign matter discharged through the first foreign matter transfer pipe; and
a sealer configured to inject the collected foreign matter into a foreign matter container and to seal the foreign matter container.

20. A pipeline maintenance apparatus comprising:
a pipeline maintenance robot configured to move along an interior of a pipeline of a semiconductor facility and to remove foreign matter from the pipeline;
a standby station on an outside of the pipeline, wherein the standby station is configured to provide an access passage for the pipeline maintenance robot and to provide a standby space for the pipeline maintenance robot to wait; and
a mobile function station configured to be selectively coupled to or separated from the standby station,
wherein the standby station comprises:
a foreign matter discharge port penetrating the standby station, wherein the foreign matter discharge port is configured to allow the foreign matter to be discharged to an outside of the standby station; and
a resource connector penetrating the standby station, wherein the resource connector is configured to allow a resource used for removal of the foreign matter by the pipeline maintenance robot to be supplied from an outside of the standby station, and
wherein the mobile function station comprises:
a foreign matter transfer pipe configured to be selectively coupled to or separated from the foreign matter discharge port, wherein the foreign matter transfer pipe is configured to move the foreign matter discharged through the foreign matter discharge port;
a collector configured to collect the foreign matter discharged through the foreign matter transfer pipe;
a foreign matter pump configured to apply a negative pressure in the foreign matter transfer pipe to move the foreign matter from the foreign matter discharge port to the collector;
a resource transfer pipe configured to allow the resource to move to the pipeline maintenance robot; and
a reel configured to accommodate the resource transfer pipe and to guide a movement of the resource transfer pipe.
